(19) United States
(12) Patent Application Publication
(10) Pub. No.: US 2025/0144765 A1
(43) Pub. Date: May 8, 2025

(54) POLISHING PAD, METHOD FOR PRODUCING POLISHING PAD, AND METHOD FOR POLISHING SURFACE OF OPTICAL MATERIAL OR SEMICONDUCTOR MATERIAL

(71) Applicant: FUJIBO Holdings, Inc., Chuo-ku, Tokyo (JP)

(72) Inventors: Yoshihide KAWAMURA, Saijo-shi, Ehime (JP); Teppei TATENO, Saijo-shi, Ehime (JP); Hiroshi KURIHARA, Saijo-shi, Ehime (JP); Satsuki NARUSHIMA, Saijo-shi, Ehime (JP); Yamato TAKAMIZAWA, Saijo-shi, Ehime (JP); Keisuke OCHI, Saijo-shi, Ehime (JP); Tetsuaki KAWASAKI, Saijo-shi, Ehime (JP)

(21) Appl. No.: 18/261,026

(22) PCT Filed: Jan. 11, 2022
(86) PCT No.: PCT/JP2022/000475

§ 371 Date: Oct. 16, 2024

(30) Foreign Application Priority Data
Jan. 14, 2021 (JP) 2021-004349
Sep. 29, 2021 (JP) 2021-159470
Sep. 29, 2021 (JP) 2021-159472

(51) Int. Cl. B24B 37/24; B24B 37/04

(52) U.S. Cl. CPC B24B 37/24; B24B 37/042

(57) ABSTRACT

An object of the present invention is to provide a polishing pad that uses a polyol different from conventionally used polyols such as PTMG as a high molecular weight polyol of an isocyanate-terminated urethane prepolymer that forms a polishing layer, a method for producing the polishing pad, and a method for polishing the surface of an optical material or a semiconductor material using the polishing pad.

A polishing pad having a polishing layer comprising a polyurethane resin,
wherein the polyurethane resin is a cured product of a curable resin composition comprising an isocyanate-terminated urethane prepolymer and a curing agent, and the isocyanate-terminated urethane prepolymer is a reaction product of a polyol component and a polyisocyanate component, and
the polyol component comprises a polyol having a carbonate group in a molecule.

### TECHNICAL FIELD

The present invention relates to a polishing pad, a method for producing the polishing pad, and a method for polishing the surface of an optical material or a semiconductor material. The polishing pad of the present invention is used for polishing optical materials, semiconductor wafers, semiconductor devices, substrates for hard disks, and others, and is suitably used for polishing devices in which oxide layers, metal layers, or other layers are formed on semiconductor wafers in particular.

### BACKGROUND ART

Optical materials, semiconductor wafers, hard disk substrates, glass substrates for liquid crystals, and semiconductor devices require very precise flatness. In order to polish the surface of such a variety of materials, in particular the surface of semiconductor devices, to a flat surface, hard polishing pads are commonly used.

Currently, for the polishing layer in many hard polishing pads, it is common to use a hard polyurethane material obtained by curing an isocyanate-terminated urethane prepolymer, which is a reaction product of an isocyanate component such as tolylene diisocyanate (TDI) and a polyol component including a high molecular weight polyol such as a polytetramethylene ether glycol (PTMG) with a curing agent such as 3,3′-dichloro-4,4′-diaminodiphenylmethane. The high molecular weight polyol that forms the isocyanate-terminated urethane prepolymer forms the soft segment of polyurethane, and from the viewpoint such as handleability and moderate rubber elasticity, PTMG has been conventionally used as the high molecular weight polyol.

### CITATION LIST

### Patent Literature

PTL 1: Japanese Patent Laid-Open No. 2011-40737
PTL 2: Japanese Patent Laid-Open No. 2020-157415

### SUMMARY OF INVENTION

### Technical Problem

A polishing pad that uses a polyol different from conventionally used polyols such as PTMG as the high molecular weight polyol of the isocyanate-terminated urethane prepolymer that forms the polishing layer is desired.

In addition, in the polishing of semiconductor devices, as integrated circuits have become finer and denser in recent years, a more rigorous level of suppression of defects such as scratches and organic residues on the surface of the workpiece to be polished is increasingly demanded. However, conventional polishing pads that use PTMG as the high molecular weight polyol are sometimes insufficient in terms of defect suppression, and thus investigations are underway to use a polyol other than PTMG as the high molecular weight polyol. Also, in the case where a polyol other than PTMG is used as the high molecular weight polyol, it is desirable that the polishing performance such as polishing rate be equivalent to or better than that of the conventional polishing pads described above.

Patent Literature 1 discloses a polishing pad including a polyurethane reaction product of a polyol blend, which is a mixture of polypropylene glycol (PPG) and PTMG, a polyamine or polyamine mixture, and toluene diisocyanate. The polishing pad of Patent Literature 1 uses a mixture of PPG and PTMG as the polyol blend that forms the polyurethane reaction product, thereby reducing the defect rate (defects).

However, in the case where a mixture of PPG and PTMG is used as the high molecular weight polyol, as in the polishing pad of Patent Literature 1, since PPG and PTMG are incompatible and it is difficult to make them completely uniform, the polymerization reaction of the isocyanate-terminated urethane prepolymer becomes non-uniform, resulting in unstable and inconsistent polishing performance.

Also, in the case where the entire amount of PTMG is replaced by PPG as the high molecular weight polyol, the resulting isocyanate-terminated urethane prepolymer tends to become soft, and in order to prevent this, a new adjustment is required in the equivalent amount of the polyol component and the polyisocyanate component upon the production of the isocyanate-terminated urethane prepolymer. Furthermore, when the present inventors investigated the polishing performance of a polishing pad in which the entire amount of PTMG was replaced by PPG as the high molecular weight polyol, as shown in Comparative Example 3A, which will be described later, although defects were suppressed compared to conventional polishing pads using PTMG as the high molecular weight polyol, a higher level of defect suppression is still demanded in order to cope with the miniaturization and densification of integrated circuits in recent years.

As described above, a polishing pad that can suppress defects in the workpiece to be polished is also desired. In addition, a polishing pad that not only suppresses defects in the workpiece to be polished but also exhibits an excellent polishing rate is also desired.

Furthermore, in the polishing of semiconductor devices, as integrated circuits have become finer and denser in recent years, a more rigorous level of improvement in level difference resolving performance and suppression of defects such as scratches on the surface of the workpiece to be polished is increasingly demanded. When the level difference resolving performance on the surface of the workpiece to be polished is inadequate, a phenomenon called dishing, in which the wiring cross-section sinks into a dish shape mainly in wide wiring patterns, is likely to occur, and the local flatness of the surface of the workpiece to be polished will be deteriorated.

Conventional polishing pads that use PTMG as the high molecular weight polyol are sometimes insufficient in terms of level difference resolving performance or defect suppression, and thus investigations are underway to use a polyol other than PTMG as the high molecular weight polyol.

Patent Literature 2 discloses that a polishing pad formed using polypropylene glycol (PPG) as the high molecular weight polyol of the isocyanate-terminated urethane prepolymer has excellent level difference resolving performance and causes less defects.

However, in the case where the entire amount of high molecular weight polyol is PPG, as in the polishing pad described in Patent Literature 2, the wear resistance of the polishing layer may be poor and the life of the polishing pad may be shortened. Also, in the case where the entire amount of high molecular weight polyol is PPG, as in the polishing pad described in Patent Literature 2, the resulting isocyanate-terminated urethane prepolymer tends to become soft, and in order to prevent this, a new adjustment is required in the equivalent amount of the polyol component and the polyisocyanate component upon the production of the isocyanate-terminated urethane prepolymer.

As described above, a polishing pad that can suppress dishing with excellent level difference resolving performance and can also suppress defects is also desired.

An object of the present invention is to provide a polishing pad that uses a polyol different from conventionally used polyols such as PTMG as the high molecular weight polyol of the isocyanate-terminated urethane prepolymer that forms the polishing layer, a method for producing the polishing pad, and a method for polishing the surface of an optical material or a semiconductor material using the polishing pad.

Also, another object of the present invention is to provide a polishing pad that can suppress defects in the workpiece to be polished, a method for producing the polishing pad, and a method for polishing the surface of an optical material or a semiconductor material using the polishing pad. In addition, another object of the present invention is to provide a polishing pad that not only suppresses defects in the workpiece to be polished but also exhibits an excellent polishing rate, a method for producing the polishing pad, and a method for polishing the surface of an optical material or a semiconductor material using the polishing pad.

Furthermore, the present invention was made in view of the above problems, and another object is to provide a polishing pad that can suppress dishing with excellent level difference resolving performance and can also suppress defects.

### Solution to Problem

As a result of diligent researches to solve the above problems, the present inventors have found that the above problems can be solved by using a polyol having a carbonate group as the polyol component that forms the isocyanate-terminated urethane prepolymer, and have completed the present invention. Specific aspects of the present invention are as follows.
[1]A polishing pad having a polishing layer comprising a polyurethane resin,
wherein the polyurethane resin is a cured product of a curable resin composition comprising an isocyanate-terminated urethane prepolymer and a curing agent, and the isocyanate-terminated urethane prepolymer is a reaction product of a polyol component and a polyisocyanate component, and
the polyol component comprises a polyol having a carbonate group in a molecule,
[2] The polishing pad according to [1], wherein the polyol having a carbonate group is a polyether polycarbonate diol represented by the following formula (I):

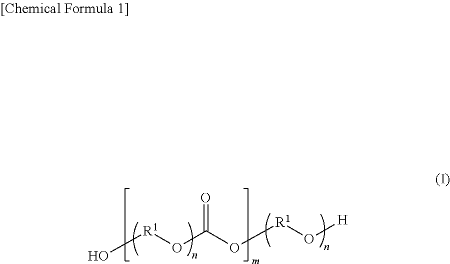

wherein
   R¹ is a divalent hydrocarbon group having 2 to 10 carbon atoms, and a plurality of R¹ is identical or different;
   n is an integer of 2 to 30; and
   m is an integer of 1 to 20.
[3] The polishing pad according to 121, wherein R¹ in the above formula (I) is a n-butylene group and/or a 2-methylbutylene group.
[4] The polishing pad according to [2] or [3], wherein the polyether polycarbonate diol comprises a structural unit derived from a polytetramethylene ether glycol, and a number average molecular weight of the structural unit derived from the polytetramethylene ether glycol is 100 to 1500.
[5] The polishing pad according to any one of [2] to [4], wherein a number average molecular weight of the polyether polycarbonate diol is 200 to 5000).
[6] The polishing pad according to [1],
   wherein the polyol component comprises a high molecular weight polyol, and the high molecular weight polyol comprises the polyol having a carbonate group in a molecule, and
   a content of the carbonate group is 1.5 to 21.0% by weight relative to the entire polyol having a carbonate group in a molecule.
[7] The polishing pad according to [6], wherein the polyol having a carbonate group in a molecule comprises a structural unit derived from a polytetramethylene ether glycol.
[8] The polishing pad according to [6] or [7], wherein the polyol having a carbonate group in a molecule comprises a polyether polycarbonate diol represented by the following formula (II):

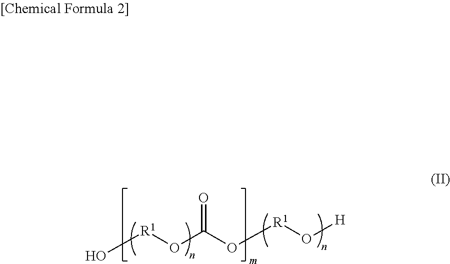

wherein
   R¹ is a divalent hydrocarbon group having 2 to 10 carbon atoms, and a plurality of R¹ is identical or different;
   n is 2 to 30; and
   m is 0.1 to 20.
[9] The polishing pad according to [8], wherein R¹ in the above formula (II) is at least one selected from the group consisting of ethylene, isopropylene, and n-butylene.
[10] The polishing pad according to any one of [6] to [19], wherein a number average molecular weight of the polyol having a carbonate group in a molecule is 200 to 5000.
[11] The polishing pad according to any one of [6] to [10], wherein the high molecular weight polyol further comprises a polyether polyol.
[12] The polishing pad according to any one of [6] to [11], wherein a content of the carbonate group in the polyol having a carbonate group in a molecule is 0.5 to 6.4% by weight relative to the entire polishing layer.
[13] The polishing pad according to [1].
   wherein the polyol component comprises a high molecular weight polyol,
   the high molecular weight polyol comprises the polyol having a carbonate group in a molecule, and a number average molecular weight of the polyol having a carbonate group in a molecule is Mna, and
   a number average molecular weight of the isocyanate-terminated urethane prepolymer is not more than Mna.
[14] The polishing pad according to [13], wherein, in molecular weight distribution in terms of polyethylene glycol/polyethylene oxide (PEG/PEO) as measured by gel permeation chromatography (GPC) of the isocyanate-terminated urethane prepolymer, a peak top molecular weight of a peak that is present in a molecular weight range of 700 to 10000 is not more than Mna+1000.
[15] The polishing pad according to [13] or [14], wherein the number average molecular weight Mna of the polyol having a carbonate group in a molecule is 500 to 2500.
[16] The polishing pad according to any one of [13] to [15], wherein the number average molecular weight of the isocyanate-terminated urethane prepolymer is 3500 or less.
[17] The polishing pad according to [16], wherein the number average molecular weight of the isocyanate-terminated urethane prepolymer is 2000 or less.
[18] The polishing pad according to any one of [13] to [17], wherein the polyol having a carbonate group in a molecule comprises a structural unit derived from a polytetramethylene ether glycol.
[19] The polishing pad according to any one of [13] to [18], wherein the polyol having a carbonate group in a molecule comprises a polyether polycarbonate diol represented by the following formula (III):

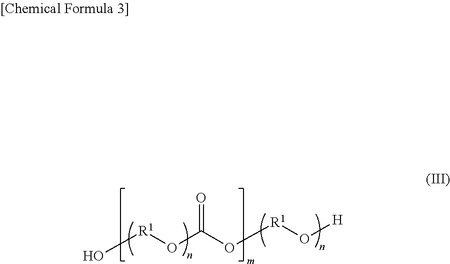

wherein
   R¹ is a divalent hydrocarbon group having 2 to 10 carbon atoms, and a plurality of R¹ is identical or different;
   n is 2 to 30; and
   m is 0.1 to 20.
[20] The polishing pad according to [19], wherein R¹ in the above formula (III) is at least one selected from the group consisting of ethylene, isopropylene, and n-butylene.
[21] The polishing pad according to any one of [13] to [20], wherein the high molecular weight polyol further comprises a polyether polyol.
[22] The polishing pad according to any one of [1] to [21], wherein the polyisocyanate component comprises tolylene diisocyanate,
[23] The polishing pad according to any one of [1] to [22], wherein the curing agent comprises 3,3′-dichloro-4,4′-diaminodiphenylmethane.
[24] The polishing pad according to any one of [1] to [23], wherein the curable resin composition further comprises a micro hollow sphere.
[25] A method for producing the polishing pad according to any one of [1] to [24], the method comprising a step of forming the polishing layer.
[26] A method for polishing a surface of an optical material or a semiconductor material, the method comprising a step of polishing a surface of an optical material or a semiconductor material using the polishing pad according to any one of [1] to [24].
   [1A] A polishing pad having a polishing layer comprising a polyurethane resin,
   in which the polyurethane resin is a cured product of a curable resin composition comprising an isocyanate-terminated urethane prepolymer and a curing agent, and the isocyanate-terminated urethane prepolymer is a reaction product of a polyol component and a polyisocyanate component, and
   the polyol component comprises a polyether polycarbonate diol represented by the following formula (I):

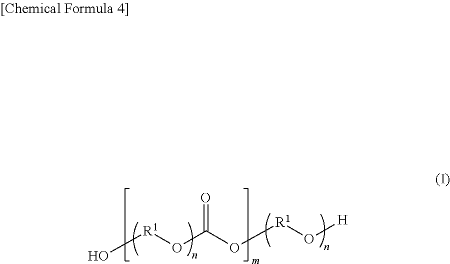

(in the above formula (I),
   R¹ is a divalent hydrocarbon group having 2 to 10 carbon atoms, and a plurality of R¹ is identical or different;
   n is an integer of 2 to 30; and
   m is an integer of 1 to 20.).
[2A] The polishing pad according to [1 A], wherein R¹ in the above formula (I) is a n-butylene group and/or a 2-methylbutylene group.
   [3A] The polishing pad according to [1A] or [2A], wherein the polyether polycarbonate diol comprises a structural unit derived from a polytetramethylene ether glycol, and a number average molecular weight of the structural unit derived from the polytetramethylene ether glycol is 100 to 1500.
   [4A] The polishing pad according to any one of [1A] to [3A], wherein a number average molecular weight of the polyether polycarbonate diol is 200 to 5000.
   [5A] The polishing pad according to any one of [1A] to [4A], wherein the polyisocyanate component comprises tolylene diisocyanate.
   [6A] The polishing pad according to any one of [1A] to [5A], wherein the curing agent comprises 3,3′-dichloro-4,4′-diaminodiphenylmethane.
   [7A] The polishing pad according to any one of [1A] to [6A], wherein the curable resin composition further comprises a micro hollow sphere.
   [8A] A method for producing the polishing pad according to any one of [1A] to [7A], the method comprising a step of forming the polishing layer.
   [9A] A method for polishing a surface of an optical material or a semiconductor material, the method comprising a step of polishing a surface of an optical material or a semiconductor material using the polishing pad according to any one of [1A] to [7A].
   [1B] A polishing pad having a polishing layer comprising a polyurethane resin,
   in which the polyurethane resin is a cured product of a curable resin composition comprising an isocyanate-terminated urethane prepolymer and a curing agent, and the isocyanate-terminated urethane prepolymer is a reaction product of a polyol component and a polyisocyanate component,
   the polyol component comprises a high molecular weight polyol, and the high molecular weight polyol comprises a polyol having a carbonate group in a molecule, and
   the content of the carbonate group is 1.5 to 21.0% by weight relative to the entire polyol having a carbonate group in a molecule.
   [2B] The polishing pad according to [1B], wherein the polyol having a carbonate group in a molecule comprises a structural unit derived from a polytetramethylene ether glycol.
   [3B] The polishing pad according to [1B] or [2B], wherein the polyol having a carbonate group in a molecule comprises a polyether polycarbonate diol represented by the following formula (II):

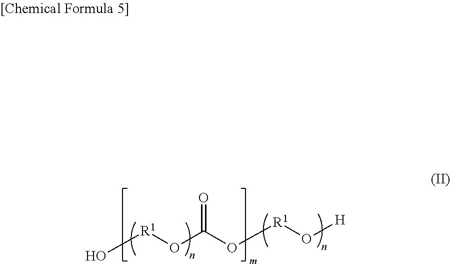

wherein
   R¹ is a divalent hydrocarbon group having 2 to 10 carbon atoms, and a plurality of R¹ is identical or different;
   n is 2 to 30; and
   m is 0.1 to 20.
[4B] The polishing pad according to [3B], wherein R¹ in the above formula (II) is at least one selected from the group consisting of ethylene, isopropylene, and n-butylene.
[5B] The polishing pad according to any one of [1B] to [4B], wherein a number average molecular weight of the polyol having a carbonate group in a molecule is 200 to 5000.
[6B] The polishing pad according to any one of [1B] to [5B], wherein the high molecular weight polyol further comprises a polyether polyol.
[7B] The polishing pad according to anyone of [1B] to [6B], wherein a content of the carbonate group in the polyol having a carbonate group in a molecule is 0.5 to 6.4% by weight relative to the entire polishing layer.
[8B] The polishing pad according to any one of [1B] to [7B], wherein the polyisocyanate component comprises tolylene diisocyanate.
[9B] The polishing pad according to any one of [1B] to [8B], wherein the curing agent comprises 3,3′-dichloro-4,4′-diaminodiphenylmethane.
[10B] The polishing pad according to anyone of [1B] to [9B], wherein the curable resin composition further comprises a micro hollow sphere.
[11B] A method for producing the polishing pad according to anyone of [1B] to [10B], the method comprising a step of forming the polishing layer.
[12B] A method for polishing a surface of an optical material or a semiconductor material, the method comprising a step of polishing a surface of an optical material or a semiconductor material using the polishing pad according to any one of [1B] to [10B].
[1C]A polishing pad having a polishing layer comprising a polyurethane resin,
in which the polyurethane resin is a cured product of a curable resin composition comprising an isocyanate-terminated urethane prepolymer and a curing agent, and the isocyanate-terminated urethane prepolymer is a reaction product of a polyol component and a polyisocyanate component.
the polyol component comprises a high molecular weight polyol,
the high molecular weight polyol comprises a polyol having a carbonate group in a molecule and having a number average molecular weight of Mna, and
the number average molecular weight of the isocyanate-terminated urethane prepolymer is not more than Mna.
[2C] The polishing pad according to [1C], wherein, in molecular weight distribution in terms of polyethylene glycol/polyethylene oxide (PEG/PEO) as measured by gel permeation chromatography (GPC) of the isocyanate-terminated urethane prepolymer, a peak top molecular weight of a peak that is present in a molecular weight range of 700 to 10000 is not more than Mna+1000.
[3C] The polishing pad according to [1C] or [2C], wherein the number average molecular weight Mna of the polyol having a carbonate group in a molecule is 500 to 2500.
[4C] The polishing pad according to any one of [1C] to [3C], wherein the number average molecular weight of the isocyanate-terminated urethane prepolymer is 3500 or less.
[5C] The polishing pad according to [4C], wherein the number average molecular weight of the isocyanate-terminated urethane prepolymer is 2000 or less.
[6C] The polishing pad according to any one of [1C] to [5C], wherein the polyol having a carbonate group in a molecule comprises a structural unit derived from a polytetramethylene ether glycol.
[7C] The polishing pad according to any one of [1C] to [6C], wherein the polyol having a carbonate group in a molecule comprises a polyether polycarbonate diol represented by the following formula (III):

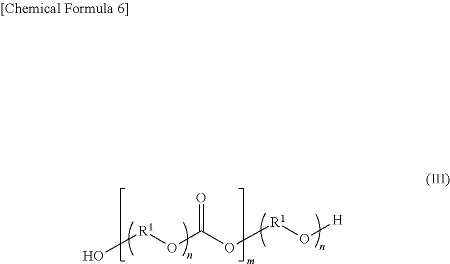

wherein
   R¹ is a divalent hydrocarbon group having 2 to 10 carbon atoms, and a plurality of R¹ is identical or different;
   n is 2 to 30; and
   m is 0.1 to 20.
[8C] The polishing pad according to [7C], wherein R¹ in the above formula (III) is at least one selected from the group consisting of ethylene, isopropylene, and n-butylene.
[9C] The polishing pad according to any one of [1C] to [8C], wherein the high molecular weight polyol further comprises a polyether polyol.
[10C] The polishing pad according to anyone of [1C] to [9C], wherein the polyisocyanate component comprises tolylene diisocyanate.
[11C] The polishing pad according to anyone of [1C] to [10C], wherein the curing agent comprises 3,3′-dichloro-4,4′-diaminodiphenylmethane.
[12C] The polishing pad according to anyone of [1C] to [11C], wherein the curable resin composition further comprises a micro hollow sphere.
[13C] A method for producing the polishing pad according to anyone of [1C] to [12C], the method comprising a step of forming the polishing layer.
[14C] A method for polishing a surface of an optical material or a semiconductor material, the method comprising a step of polishing a surface of an optical material or a semiconductor material using the polishing pad according to any one of [1C] to [12C].

### Definition

In the present application, when a numerical range is expressed by using “X to Y”, the range shall include X and Y, the numerical values at both ends of the range.

### Advantageous Effects of Invention

The present invention can provide a polishing pad that uses a polyol different from conventionally used polyols such as PTMG as the high molecular weight polyol of the isocyanate-terminated urethane prepolymer that forms the polishing layer.

A polishing pad according to one embodiment of the present invention can suppress defects in the workpiece to be polished. In addition, a polishing pad according to one embodiment of the present invention not only suppresses defects in the workpiece to be polished but also exhibits an excellent polishing rate.

A polishing pad according to another embodiment of the present invention can suppress dishing with excellent level difference resolving performance and can also suppress defects.

### BRIEF DESCRIPTION OF DRAWINGS

FIG. 1 is a graph showing the evaluation results for defects of the polishing pads of Example 1 A and Comparative Examples 1A to 3A.

FIG. 2 is a graph showing the evaluation results for polishing rate of the polishing pads of Example 1A and Comparative Examples 1A to 3A.

FIG. 3 is a graph showing the evaluation results for defects of the polishing pad of Example 4A.

FIG. 4 is a graph showing the evaluation results for polishing rate of the polishing pad of Example 4A.

FIG. 5 (a) to (c) are schematic diagrams showing the state in which a level difference is being resolved by polishing.

FIG. 6 is a graph showing the relationship between polishing amount and level difference.

FIGS. 7 (a) and (b) are graphs showing the evaluation results for level difference resolving performance of the polishing pads of Examples 1B and 10B and Comparative Examples 1B and 8B.

FIGS. 8 (c) and (d) are graphs showing the evaluation results for level difference resolving performance of the polishing pads of Examples 1B and 10B and Comparative Examples 1B and 8B.

FIG. 9 is a graph showing the evaluation results for defects of the polishing pads of Examples 1B and 10B and Comparative Examples 1B and 8B.

FIG. 10 (a) to (c) are schematic diagrams showing the state in which a level difference is being resolved by polishing.

FIG. 11 is a graph showing the relationship between polishing amount and level difference.

FIG. 12 is a graph showing the results of GPC measurement of the isocyanate-terminated urethane prepolymers used in Examples 1C and 2C and Comparative Examples 1C and 2C.

FIGS. 13 (a) and (b) are graphs showing the evaluation results for level difference resolving performance of the polishing pads of Examples 1C and 2C and Comparative Examples 1C and 2C.

FIGS. 14 (c) and (d) are graphs showing the evaluation results for level difference resolving performance of the polishing pads of Examples 1C and 2C and Comparative Examples 1C and 2C.

FIG. 15 is a graph showing the evaluation results for defects of the polishing pads of Examples 1C and 2C and Comparative Examples 1C and 2C.

### DESCRIPTION OF EMBODIMENTS

A polishing pad of the present invention is
a polishing pad having a polishing layer comprising a polyurethane resin,
in which the polyurethane resin is a cured product of a curable resin composition comprising an isocyanate-terminated urethane prepolymer and a curing agent, and the isocyanate-terminated urethane prepolymer is a reaction product of a polyol component and a polyisocyanate component, and
the polyol component comprises a polyol having a carbonate group in a molecule.

Examples of the polishing pad of the present invention include the polishing pads according to the first to third embodiments described below.

### First Embodiment

### (Action)

As a result of diligent researches on the relationship between the polyol component that forms the isocyanate-terminated urethane prepolymer and defects, the present inventors have unexpectedly found that the use of a polyether polycarbonate diol having a particular structure as the polyol component that forms the isocyanate-terminated urethane prepolymer can provide a polishing pad that can suppress the occurrence of defects. The details of why such a characteristic is obtained are not clear, but are inferred as follows.

The polyether polycarbonate diol (PEPCD) represented by the above formula (I) is considered to have lower crystallinity compared to PTMG since it has a carbonate group, and the isocyanate-terminated urethane prepolymer formed from such PEPCD is also considered to have lower crystallinity. When the crystallinity of the isocyanate-terminated urethane prepolymer that forms the polishing layer is lowered, it is considered that scraps of the polishing layer generated during polishing are less likely to be aggregated to form large lumps, and as a result, it is inferred that defects in the workpiece to be polished can be suppressed.

### Definition

In the first embodiment, the term “particles” means residual fine particles contained in polishing slurry or the like that adhere to the surface of the workpiece to be polished.

In the first embodiment, the term “pad scraps” means scraps of the polishing layer generated by wear of the surface of the polishing layer in the polishing pad during the polishing step, which adhere to the surface of the workpiece to be polished.

In the first embodiment, the term “scratches” means scratches on the surface of the workpiece to be polished.

In the first embodiment, the term “defects” is a generic term for defects including the above-mentioned particles, pad scraps, scratches, and others.

Hereinafter, a polishing pad according to the first embodiment, a method for producing the polishing pad, and a method for polishing the surface of an optical material or a semiconductor material will be described.

### 1. Polishing Pad, Method for Producing Polishing Pad

The polishing pad according to the first embodiment is a polishing pad having a polishing layer including a polyurethane resin, in which the polyurethane resin is a cured product of a curable resin composition containing an isocyanate-terminated urethane prepolymer and a curing agent, and the isocyanate-terminated urethane prepolymer is a reaction product of a polyol component and a polyisocyanate component, and the polyol component includes a polyether polycarbonate diol represented by the following formula (I):

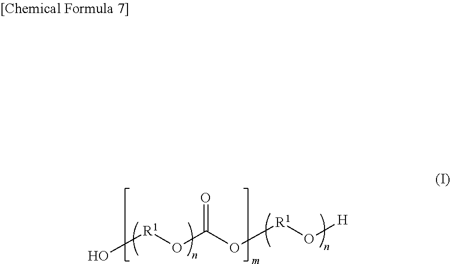

(in the above formula (I),
R¹ is a divalent hydrocarbon group having 2 to 10 carbon atoms, and a plurality of R¹ is identical or different;
n is an integer of 2 to 30; and
m is an integer of 1 to 20.).

The polishing pad according to the first embodiment has a polishing layer including a polyurethane resin. The polishing layer is disposed at a position in direct contact with a material to be polished, while other portions of the polishing pad may be constituted by a material for supporting the polishing pad, for example, a material that is rich in elasticity, such as rubber. Depending on the rigidity of the polishing pad, the polishing layer can be used as the polishing pad.

The polishing pad according to the first embodiment does not greatly differ in shape from general polishing pads except that it can suppress defects in the workpiece to be polished, and can be used in the same manner as general polishing pads. For example, it is possible to perform polishing by pressing the polishing layer against the material to be polished while rotating the polishing pad, or it is possible to perform polishing by pressing the material to be polished against the polishing layer while rotating the material to be polished.

The polishing pad according to the first embodiment can be created by generally known production methods such as mold molding and slab molding. It is produced as follows: at first, a block of polyurethane is formed by the above production methods, the block is formed into a sheet by slicing or other means, and a polishing layer formed from the polyurethane resin is molded and then pasted to a support or other material. Alternatively, the polishing layer can be molded directly on the support.

More specifically, the polishing layer becomes a polishing pad according to the first embodiment by attaching double-sided tape to the side opposite to the polishing surface of the polishing layer and cutting it into a predetermined shape. There is no particular restriction on the double-sided tape, and any double-sided tape known in the art can be arbitrarily selected for use. In addition, the polishing pad according to the first embodiment may have a single layer structure composed only of the polishing layer, or it may be composed of multiple layers with other layers (underlayer and support layer) pasted to the side opposite to the polishing surface of the polishing layer.

The polishing layer is molded by preparing a curable resin composition containing an isocyanate-terminated urethane prepolymer and a curing agent and curing the curable resin composition.

The polishing layer can be constituted by a foamed polyurethane resin, and foaming can be carried out by dispersing a foaming agent containing micro hollow spheres in the polyurethane resin. In this case, the polishing layer can be molded by preparing a curable resin composition containing an isocyanate-terminated urethane prepolymer, a curing agent, and a foaming agent, and foaming and curing the curable resin composition.

The curable resin composition can be, for example, a two-component composition prepared by mixing liquid A containing an isocyanate-terminated urethane prepolymer and liquid B containing a curing agent component. The other components may be added to liquid A or may be added to liquid B, but in the case where problems arise, it can be a composition constituted by further dividing the components into multiple liquids and mixing three or more liquids.

### (Isocyanate-Terminated Urethane Prepolymer)

The isocyanate-terminated urethane prepolymer is a product obtained by allowing the polyol component to react with the polyisocyanate component, and the polyol component includes the polyether polycarbonate diol represented by the above formula (I).

The NCO equivalent (g/eq) of the isocyanate-terminated urethane prepolymer is preferably less than 600, more preferably 350 to 550, and most preferably 400 to 500. When the NCO equivalent (g/eq) is within the above numerical range, a polishing pad with moderate polishing performance can be obtained.

### (Polyol Component)

In the above formula (I) representing the above polyether polycarbonate diol, R¹ is a divalent hydrocarbon group having 2 to 10 carbon atoms, and examples of R¹ include ethylene, n-propylene, isopropylene, n-butylene, isobutylene, 1,1-dimethylethylene, n-pentylene, 2,2-dimethylpropylene, and 2-methylbutylene, and in particular, it is preferable that it be a n-butylene group and/or a 2-methylbutylene group. In the above formula (I), a plurality of R¹ is identical or different, but it is preferable that they be identical.

In the above formula (I), n is an integer of 2 to 30, preferably an integer of 3 to 15, and more preferably an integer of 3 to 10.

In the above formula (I), m is an integer of 1 to 20, preferably an integer of 1 to 10, and more preferably an integer of 1 to 5.

It is preferable that the above polyether polycarbonate diol include a structural unit derived from a polytetramethylene ether glycol, and it is preferable that the structural unit derived from the polytetramethylene ether glycol be the moiety represented by —(R¹—O)ₙ— in the above formula (I). The number average molecular weight of the structural unit derived from the polytetramethylene ether glycol is preferably 100 to 1500, more preferably 150 to 1000, and most preferably 200 to 850.

The number average molecular weight of the above polyether polycarbonate diol is preferably 200 to 5000, more preferably 500 to 3000, and most preferably 800 to 2500.

The number average molecular weight of the structural unit derived from the above polytetramethylene ether glycol and the above polyether polycarbonate diol can be measured as the molecular weight in terms of polystyrene based on gel permeation chromatography (GPC) under the following conditions.

### <Measurement Conditions>

Column: Ohpak SB-802.5 HQ (exclusion limit 10000)
Mobile phase: 5 mM LiBr/DMF
Flow rate: 0.5 ml/min (26 kg/cm²)
Oven: 60° C.
Detector: RI 40° C.
Sample volume: 20 μl

The content of the above polyether polycarbonate diol relative to the entire isocyanate-terminated urethane prepolymer is preferably 25 to 75% by weight, more preferably 35 to 65% by weight, and most preferably 40 to 60% by weight. When the content of the above polyether polycarbonate diol is within the above numerical range, defects in the workpiece to be polished can be suppressed and a high polishing rate can be achieved.

Examples of the polyol component other than the above polyether polycarbonate diol included in the isocyanate-terminated urethane prepolymer include a low molecular weight polyol, a high molecular weight polyol other than the above polyether polycarbonate diol, or a combination thereof. In the first embodiment, the low molecular weight polyol is a polyol having a number average molecular weight of 30 to 300, and the high molecular weight polyol is a polyol having a number average molecular weight of greater than 300. The number average molecular weight of the above low molecular weight polyol and the high molecular weight polyol other than the above polyether polycarbonate diol can be measured by the same method as shown in the number average molecular weight of the structural unit derived from the above polytetramethylene ether glycol and the above polyether polycarbonate diol.

Examples of the above low molecular weight polyol include ethylene glycol, diethylene glycol, triethylene glycol, 1,2-propanediol, 1,3-propanediol, 1,3-butanediol, 1,4-butanediol, neopentyl glycol, pentanediol, 3-methyl-1,5-pentanediol, 1,6-hexanediol, or a combination thereof.

Examples of the high molecular weight polyol other than the above polyether polycarbonate diol include:
a polyether polyol such as polytetramethylene ether glycol (PTMG), polyethylene glycol, or polypropylene glycol;
a polyester polyol such as a reaction product of ethylene glycol and adipic acid or a reaction product of butylene glycol and adipic acid;
a polycarbonate polyol;
a polycaprolacton polyol;
or a combination thereof.

The content of the above polyether polycarbonate diol relative to the entire high molecular weight polyol is preferably 80 to 100% by weight, more preferably 85 to 100% by weight, and most preferably 90 to 100% by weight. When the content of the above polyether polycarbonate diol is within the above numerical range, defects in the workpiece to be polished can be suppressed and a high polishing rate can be achieved.

Also, it is possible for the above high molecular weight polyol to consist of the above polyether polycarbonate diol.

### (Polyisocyanate Component)

Examples of the polyisocyanate component included in the isocyanate-terminated urethane prepolymer include:
m-phenylene diisocyanate;
p-phenylene diisocyanate;
2,6-tolylene diisocyanate (2,6-TDI);
2,4-tolylene diisocyanate (2,4-TDI);
naphthalene-1,4-diisocyanate;
diphenylmethane-4,4′-diisocyanate (MDI);
4,4′-methylene-bis(cyclohexyl isocyanate) (hydrogenated MDI);
3,3′-dimethoxy-4,4′-biphenyl diisocyanate;
3,3′-dimethyldiphenylmethane-4,4′-diisocyanate;
xylylene-1,4-diisocyanate;
4,4′-diphenylpropane diisocyanate
trimethylene diisocyanate;
hexamethylene diisocyanate;
propylene-1,2-diisocyanate;
butylene-1,2-diisocyanate;
cyclohexylene-1,2-diisocyanate;
cyclohexylene-1,4-diisocyanate;
p-phenylene diisothiocyanate;
xylylene-1,4-diisothiocyanate;
ethylidyne diisothiocyanate; or
a combination thereof.

Among these, from the viewpoint of polishing characteristic, mechanical strength, and other properties of the resulting polishing pad, it is preferable to use tolylene diisocyanate such as 2,6-tolylene diisocyanate (2,6-TDI) and 2,4-tolylene diisocyanate (2,4-TDI).

### (Curing Agent)

Examples of the curing agent contained in the curable resin compositions include an amine curing agent, which will be described below.

Examples of the polyamine that constitutes the amine curing agent include a diamine, and examples thereof include an alkylenediamine such as ethylenediamine, propylenediamine, or hexamethylenediamine; a diamine having an aliphatic ring such as isophoronediamine or dicyclohexylmethane-4,4′-diamine; a diamine having an aromatic ring such as 3,3′-dichloro-4,4′-diaminodiphenylmethane (another name: methylenebis-o-chloroaniline) (hereinafter, abbreviated as MOCA); a diamine having a hydroxy group, in particular, a hydroxyalkylalkylenedianine, such as 2-hydroxyethylethylenediamine, 2-hydroxyethylpropylenediamine, di-2-hydroxyethylethylenediamine, di-2-hydroxyethylpropylenediamine, 2-hydroxypropylethylenediamine, or di-2-hydroxypropylethylenediamine; or a combination thereof. In addition, it is also possible to use a tri-functional triamine compound and a tetra- or higher-functional polyamine compound.

The particularly preferred curing agent is the above-mentioned MOCA, and it is also possible for the curing agent to consist of MOCA. The chemical structure of this MOCA is as follows.

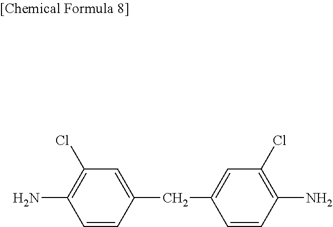 [SMILES: Nc1ccc(Cc2ccc(N)c(Cl)c2)cc1Cl]

As for the amount of the entire curing agent, an amount is used that provides a ratio of the number of moles of NH₂ in the curing agent to the number of moles of NCO in the isocyanate-terminated urethane prepolymer (number of moles of NH₂/number of moles of NCO) of preferably 0.7 to 1.1, more preferably 0.75 to 1.0, and most preferably 0.8 to 0.95.

### (Micro Hollow Spheres)

In the first embodiment, the curable resin composition can further contain a micro hollow sphere (micro hollow spheres).

By mixing the micro hollow spheres into the polyurethane resin, a foamed product can be formed. The micro hollow spheres refer to unfoamed thermoexpandable microspheres composed of an outer shell (polymer shell) composed of a thermoplastic resin and a low boiling point hydrocarbon encapsulated in the outer shell, and those formed by thermally expanding the unfoamed thermoexpandable microspheres. As the polymer shell, for example, a thermoplastic resin such as an acrylonitrile-vinylidene chloride copolymer, an acrylonitrile-methyl methacrylate copolymer, or a vinyl chloride-ethylene copolymer can be used. Similarly, as the low boiling point hydrocarbon encapsulated in the polymer shell, for example, isobutane, pentane, isopentane, petroleum ether, or a combination thereof can be used.

### (Other Components)

In addition, it is also possible to add a catalyst or others commonly used in the art to the curable resin composition.

It is also possible to add the above-mentioned polyisocyanate component to the curable resin composition later, and the weight proportion of the additional polyisocyanate component relative to the total weight of the isocyanate-terminated urethane prepolymer and the additional polyisocyanate component is preferably 0.1 to 10% by weight, more preferably 0.5 to 8% by weight, and particularly preferably 1 to 5% by weight.

As the polyisocyanate component to be additionally added to the polyurethane resin curable composition, the above-mentioned polyisocyanate components can be used without particular limitation, but 4,4′-methylene-bis(cyclohexyl isocyanate) (hydrogenated MDI) is preferred.

### 2. Method for Polishing Surface of Optical Material or Semiconductor Material

The method for polishing the surface of an optical material or a semiconductor material according to the first embodiment includes a step of polishing the surface of an optical material or a semiconductor material using the above-mentioned polishing pad.

The method for polishing the surface of an optical material or a semiconductor material according to the first embodiment can further include a step of supplying slurry to the surface of the polishing pad, the surface of the optical material or the semiconductor material, or both of them.

### (Slurry)

The liquid component contained in the slurry is not particularly limited, examples of which include water (pure water), an acid, an alkali, an organic solvent, or a combination thereof, and it is selected according to the material of the workpiece to be polished, the desired polishing conditions, and other factors. It is preferable for the slurry to be composed mainly of water (pure water), and preferable to contain 80% by weight or more of water relative to the entire slurry. The abrasive grain component contained in the slurry is not particularly limited, examples of which include silica, zirconium silicate, cerium oxide, aluminum oxide, manganese oxide, or a combination thereof. The slurry may contain other components such as an organic matter that is soluble in the liquid component and a pH adjuster.

### Second Embodiment

### (Action)

As a result of diligent researches on the relationship between the polyol component that forms the isocyanate-terminated urethane prepolymer and level difference resolving performance and defects, the present inventors have unexpectedly found that the use of a polyol having a carbonate group in a molecule with a content of the carbonate group of 1.5 to 21.0% by weight as the polyol component that forms the isocyanate-terminated urethane prepolymer can provide a polishing pad that can suppress dishing with excellent level difference resolving performance and can also suppress defects. The details of why such a characteristic is obtained are not clear, but are inferred as follows.

The polyol having a carbonate group in a molecule with a content of the carbonate group of 1.5 to 21.0% by weight is considered to have lower crystallinity compared to PTMG since it has the carbonate group with a moderate content, and the isocyanate-terminated urethane prepolymer formed from such a polyol having a carbonate group in a molecule is also considered to have lower crystallinity. When the crystallinity of the isocyanate-terminated urethane prepolymer that forms the polishing layer is lowered, it is considered that scraps of the polishing layer generated during polishing are less likely to be aggregated to form large lumps, and as a result, it is inferred that dishing can be suppressed with improved level difference resolving performance and defects can also be suppressed in the workpiece to be polished.

### (Level Difference Resolving Performance)

The damascene process is known as a method for producing metal (Cu) wiring in the semiconductor manufacturing process. In this damascene process, grooves are dug in an insulating film on a silicon wafer, metal is embedded in these grooves by sputtering or other means, and excess metal is removed by chemical mechanical polishing (CMP) to form metal wiring. Usually, the insulating film is covered with a barrier metal before embedding the metal in order to resolve the physical or chemical stress occurring between the insulating film and the metal.

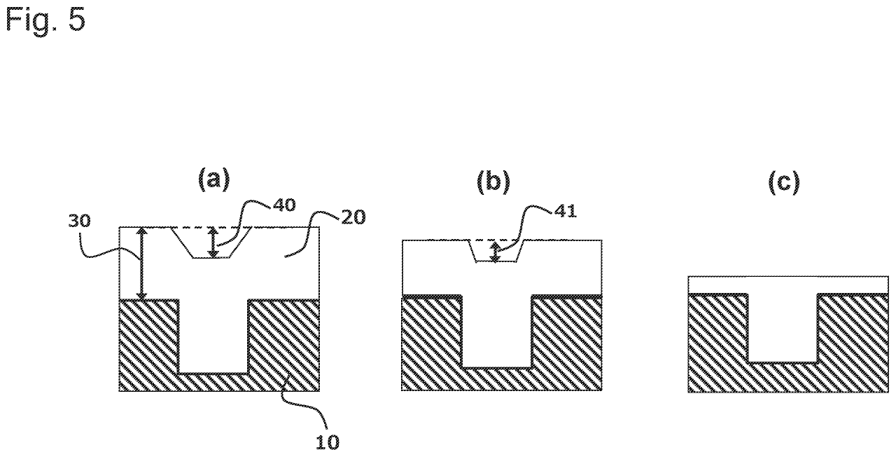

Schematic diagrams of an experiment to evaluate the level difference resolving performance are shown in FIG. 5 (a) to (c). FIG. 5 (a) shows the state before initiating polishing. As shown in FIG. 5 (a), when a metal film (Cu film) 20 is embedded in a groove of an insulating film (oxide film) 10, a level difference depending on the width and depth of the groove (difference in thickness between the portion where the groove is not present and the portion where the groove is present) 40 occurs between the portion where the groove is present and the portion where the groove is not present, depending on the width of the groove that is present under the metal film 20. In FIG. 5 (a), the thickness 30 of the metal film 20 in the portion where the groove is not present is 8000 Å, and the level difference 40 is 3500 Å. FIG. 5 (b) shows the state where the polishing amount is 2000 Å, and the level difference 41 is 2000 Å. FIG. 5 (c) shows the state where the polishing amount is 6000 Å, and the level difference 42 is almost 0.

In the second embodiment, the term “level difference resolving performance” refers to the performance of reducing level differences of patterned wafers having level differences (irregularities) as mentioned above when polishing is carried out.

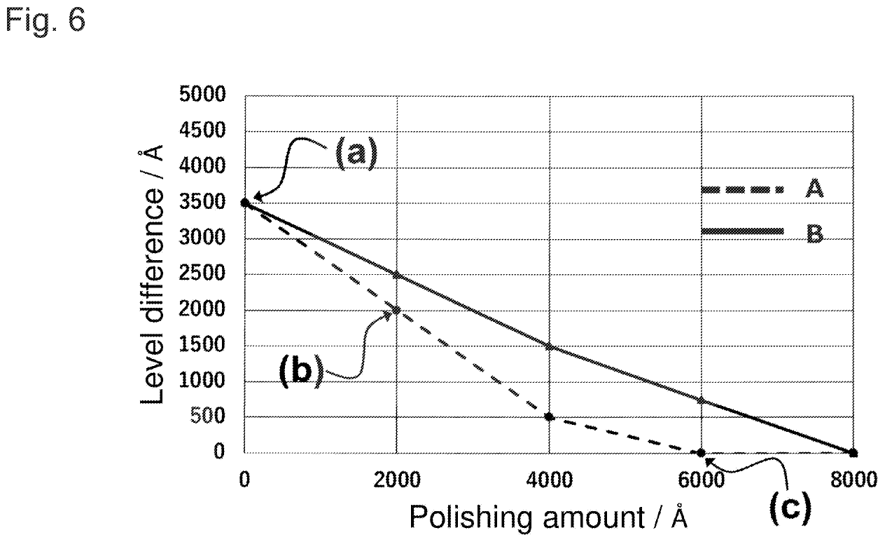

FIG. 6 shows a graph indicating the relationship between the polishing amount (Å) and the level difference (Å) in the case where polishing pad A with high level difference resolving performance (dotted line) and polishing pad B with relatively low level difference resolving performance (solid line) are used for a workpiece to be polished in the state of FIG. 5 (a). The locations marked with (a) to (c) regarding polishing pad A in FIG. 6 correspond to the states of FIG. 5 (a) to (c), respectively. In FIG. 6, although there is no difference in the level difference between the dotted line and the solid line at the time before initiating polishing (location of (a)), it is shown that polishing pad A (dotted line) results in a smaller level difference compared to polishing pad B (solid line) when polishing proceeds and the polishing amount is 2000 Å (location of (b)). Also, as can be seen from FIG. 6, polishing pad A (dotted line) resolves the level difference earlier compared to polishing pad B (solid line) (location of (c)). From the results of FIG. 6, it can be said that polishing pad A, shown by the dotted line, has relatively higher level difference resolving performance compared to polishing pad B, shown by the solid line.

### (Defects)

Also, in the second embodiment, the term “defects” means a generic term for defects including “particles”, which refer to residual fine particles that adhere to the surface of the workpiece to be polished. “pad scraps”, which refer to scraps of the polishing layer that adhere to the surface of the workpiece to be polished, “scratches”, which refer to scratches on the surface of the workpiece to be polished, and others, and the defect performance refers to the performance of reducing these “defects”.

Hereinafter, a polishing pad according to the second embodiment, a method for producing the polishing pad, and a method for polishing the surface of an optical material or a semiconductor material will be described.

### 1. Polishing Pad, Method for Producing Polishing Pad

In the second embodiment, the polishing pad is a polishing pad having a polishing layer including a polyurethane resin, in which the polyurethane resin is a cured product of a curable resin composition containing an isocyanate-terminated urethane prepolymer and a curing agent, and the isocyanate-terminated urethane prepolymer is a reaction product of a polyol component and a polyisocyanate component,
the polyol component includes a high molecular weight polyol, and the high molecular weight polyol includes a polyol having a carbonate group in a molecule, and
the content of the carbonate group is 1.5 to 21.0% by weight relative to the entire polyol having a carbonate group in a molecule.

### (Polishing Pad)

The polishing pad according to the second embodiment has a polishing layer including a polyurethane resin. The polishing layer is disposed at a position in direct contact with a material to be polished, while other portions of the polishing pad may be constituted by a material for supporting the polishing pad, for example, a material that is rich in elasticity, such as rubber. Depending on the rigidity of the polishing pad, the polishing layer can be used as the polishing pad.

The polishing pad according to the second embodiment does not greatly differ in shape from general polishing pads except that it can suppress dissing and defects in the workpiece to be polished, and can be used in the same manner as general polishing pads. For example, it is possible to perform polishing by pressing the polishing layer against the material to be polished while rotating the polishing pad, or it is possible to perform polishing by pressing the material to be polished against the polishing layer while rotating the material to be polished.

The polishing pad according to the second embodiment can be created by generally known production methods such as mold molding and slab molding. It is produced as follows: at first, a block of polyurethane is formed by the above production methods, the block is formed into a sheet by slicing or other means, and a polishing layer formed from the polyurethane resin is molded and then pasted to a support or other material. Alternatively, the polishing layer can be molded directly on the support.

More specifically, the polishing layer becomes a polishing pad by attaching double-sided tape to the side opposite to the polishing surface of the polishing layer and cutting it into a predetermined shape. There is no particular restriction on the double-sided tape, and any double-sided tape known in the art can be arbitrarily selected for use. In addition, the polishing pad may have a single layer structure composed only of the polishing layer, or it may be composed of multiple layers with other layers (underlayer and support layer) pasted to the side opposite to the polishing surface of the polishing layer.

The polishing layer is molded by preparing a curable resin composition containing an isocyanate-terminated urethane prepolymer and a curing agent and curing the curable resin composition.

The polishing layer can be constituted by a foamed polyurethane resin, and foaming can be carried out by dispersing a foaming agent containing micro hollow spheres in the polyurethane resin. In this case, the polishing layer can be molded by preparing a curable resin composition containing an isocyanate-terminated urethane prepolymer, a curing agent, and a foaming agent, and foaming and curing the curable resin composition.

The curable resin composition can be, for example, a two-component composition prepared by mixing liquid A containing an isocyanate-terminated urethane prepolymer and liquid B containing a curing agent component. The other components may be added to liquid A or may be added to liquid B, but in the case where problems arise, it can be a composition constituted by further dividing the components into multiple liquids and mixing three or more liquids.

### (Isocyanate-Terminated Urethane Prepolymer)

In the second embodiment, the isocyanate-terminated urethane prepolymer is a product obtained by allowing the polyol component to react with the polyisocyanate component, the polyol component includes the high molecular weight polyol, and the high molecular weight polyol includes the above-mentioned polyol having a carbonate group in a molecule.

The NCO equivalent (g/eq) of the isocyanate-terminated urethane prepolymer is preferably less than 600, more preferably 350 to 550, and most preferably 400 to 500. When the NCO equivalent (g/eq) is within the above numerical range, a polishing pad with moderate polishing performance can be obtained.

### (Polyol Component)

The above-mentioned polyol having a carbonate group in a molecule is one type of high molecular weight polyol.

In the second embodiment, the content of the carbonate group (—OC(═O)O—) relative to the entire polyol having a carbonate group in a molecule is 1.5 to 21.0% by weight, and it can also be 3 to 20% by weight, 5 to 19% by weight, or 10 to 18% by weight. When the content of the carbonate group relative to the entire polyol having a carbonate group in a molecule is within the above numerical range, it is possible to obtain a polishing pad that can suppress dishing with excellent level difference resolving performance and can also suppress defects.

The content of the carbonate group relative to the entire polyol having a carbonate group in a molecule can be calculated as follows:

{(number of carbonate group)×(molecular weight of carbonate group)}/(number average molecular weight of polyol having carbonate group in molecule)×100 (molecular weight of carbonate group: 60).

It is preferable that the polyol having a carbonate group in a molecule include a structural unit derived from a polytetramethylene ether glycol. The number average molecular weight of the structural unit derived from the polytetramethylene ether glycol is preferably 100 to 1500, more preferably 150 to 1000, and most preferably 200 to 850.

It is preferable that the polyol having a carbonate group in a molecule include a polyether polycarbonate diol represented by the following formula (II), and it is more preferable that it consist of the polyether polycarbonate diol represented by the following formula (II):

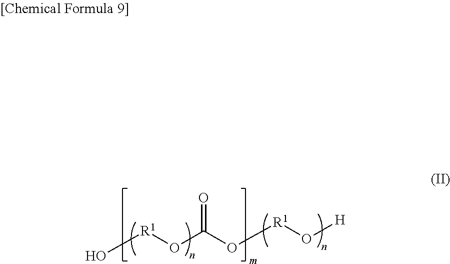

(in the above formula (II),
R¹ is a divalent hydrocarbon group having 2 to 10 carbon atoms, and a plurality of R¹ is identical or different;
n is 2 to 30; and
m is 1 to 20.).

In the case where the polyol having a carbonate group in a molecule is the polyether polycarbonate diol represented by the above formula (II), the content of the carbonate group relative to the entire polyol having a carbonate group in a molecule can be calculated based on the following expression (1):

$$\begin{matrix}[ Formula 1 ] & \\ content of carbonate group ( \% by weight ) = \{ m \times ( molecular weight of carbonate group ) \} / ( number average molecular weight of polyol having carbonate group in molecule ) \times 100 & ( 1 )\end{matrix}$$

In the above formula (II) representing the above polyether polycarbonate diol, R¹ is a divalent hydrocarbon group having 2 to 10 carbon atoms, and examples of R¹ include ethylene, n-propylene, isopropylene, n-butylene, isobutylene, 1,1-dimethylethylene, n-pentylene, 2,2-dimethylpropylene, 2-methylbutylene, or a combination of two or more types among them. In particular, it is preferable that it be at least one selected from the group consisting of ethylene, isopropylene, and n-butylene. In the above formula (II), a plurality of R¹ is identical or different, but it is preferable that they be identical. Note that, when R¹ has 6 or more carbon atoms, such as n-hexene, the crystallinity of the polyether polycarbonate diol is increased, and the flexibility, elongation, and bendability of the resulting polishing pad at low temperatures will be deteriorated, which may be unfavorable. From such a viewpoint, R¹ is preferably a divalent hydrocarbon group having 2 to 5 carbon atoms.

In the above formula (II), n is 2 to 30, preferably 3 to 20, and more preferably 3 to 15.

In the above formula (II), m is 0.1 to 20, preferably 0.5 to 10, and more preferably 1 to 5.

In the case where the polyol having a carbonate group in a molecule includes the structural unit derived from the polytetramethylene ether glycol and also includes the polyether polycarbonate diol represented by the above formula (II), it is preferable that the structural unit derived from the polytetramethylene ether glycol be the moiety represented by —(R¹—O)ₙ— in the above formula (II).

The number average molecular weight of the polyol having a carbonate group in a molecule is preferably 200 to 5000, more preferably 500 to 3000, and most preferably 800 to 2500.

The number average molecular weight of the structural unit derived from the above polytetramethylene ether glycol and the above polyol having a carbonate group in a molecule can be measured as the molecular weight in terms of polyethylene glycol/polyethylene oxide (PEG/PEO) based on gel permeation chromatography (GPC) under the following conditions.

### <Measurement Conditions>

Column: Ohpak SB-802.5 HQ (exclusion limit 10000)+SB-803 HQ (exclusion limit 100000)
Mobile phase: 5 mM LiBr/DMF
Flow rate: 0.3 ml/min (26 kg/cm²)
Oven: 60° C.
Detector: R¹ 40° C.
Sample volume: 20 μl

The content of the above polyol having a carbonate group in a molecule relative to the entire isocyanate-terminated urethane prepolymer is preferably 15 to 75% by weight, more preferably 20 to 65% by weight, and most preferably 25 to 60% by weight. When the content of the above polyol having a carbonate group in a molecule is within the above numerical range, it is possible to obtain a polishing pad that can suppress dishing with excellent level difference resolving performance and can also suppress defects.

Examples of the polyol component other than the above polyol having a carbonate group in a molecule included in the isocyanate-terminated urethane prepolymer include a low molecular weight polyol, a high molecular weight polyol other than the above polyol having a carbonate group in a molecule, or a combination thereof. In the second embodiment, the low molecular weight polyol is a polyol having a number average molecular weight of 30 to 300, and the high molecular weight polyol is a polyol having a number average molecular weight of greater than 300. The number average molecular weight of the above low molecular weight polyol and the high molecular weight polyol other than the above polyol having a carbonate group in a molecule can be measured by the same method as shown in the number average molecular weight of the structural unit derived from the above polytetramethylene ether glycol and the above polyether polycarbonate diol.

Examples of the above low molecular weight polyol include ethylene glycol, diethylene glycol, triethylene glycol, 1,2-propanediol, 1,3-propanediol, 1,3-butanediol, 1,4-butanediol, neopentyl glycol, pentanediol, 3-methyl-1,5-pentanediol, 1,6-hexanediol, or a combination of two or more types among them, and among them, diethylene glycol is preferred.

The content of the low molecular weight polyol relative to the entire isocyanate-terminated urethane prepolymer can be 0 to 20% by weight, 2 to 15% by weight, or 3 to 10% by weight. Alternatively, the content of the above low molecular weight polyol can be 0% by weight (the low molecular weight polyol is not included). In the second embodiment, the expression “not included” means that a component is not added intentionally, and does not exclude its inclusion as an impurity.

Examples of the high molecular weight polyol other than the above polyol having a carbonate group in a molecule include:
a polyether polyol such as polytetramethylene ether glycol (PTMG), polyethylene glycol, or polypropylene glycol;
a polyester polyol such as a reaction product of ethylene glycol and adipic acid or a reaction product of butylene glycol and adipic acid;
a polycarbonate polyol;
a polycaprolacton polyol; or
a combination of two or more types among them.

In the second embodiment, it is preferable that the high molecular weight polyol further include a polyether polyol.

The content of the high molecular weight polyol (including the above polyol having a carbonate group in a molecule) relative to the entire isocyanate-terminated urethane prepolymer is preferably 25 to 75% by weight, more preferably 35 to 65% by weight, and most preferably 40 to 60% by weight.

The content of the high molecular weight polyol other than the above polyol having a carbonate group in a molecule relative to the entire isocyanate-terminated urethane prepolymer is preferably 15 to 75% by weight, more preferably 20 to 65% by weight, and most preferably 25 to 60% by weight.

Also, it is possible for the above high molecular weight polyol to consist of the above polyol having a carbonate group in a molecule, or to consist of the above polyol having a carbonate group in a molecule and a polyether polyol.

### (Polyisocyanate Component)

Examples of the polyisocyanate component included in the isocyanate-terminated urethane prepolymer include:
m-phenylene diisocyanate;
p-phenylene diisocyanate;
2,6-tolylene diisocyanate (2,6-TDI);
2,4-tolylene diisocyanate (2,4-TDI);
naphthalene-1,4-diisocyanate;
diphenylmethane-4,4′-diisocyanate (MDI);
4,4′-methylene-bis(cyclohexyl isocyanate) (hydrogenated MDI);
3,3′-dimethoxy-4,4′-biphenyl diisocyanate;
3,3′-dimethyldiphenylmethane-4,4′-diisocyanate;
xylylene-1,4-diisocyanate;
4,4′-diphenylpropane diisocyanate
trimethylene diisocyanate;
hexamethylene diisocyanate;
propylene-1,2-diisocyanate;
butylene-1,2-diisocyanate;
cyclohexylene-1,2-diisocyanate;
cyclohexylene-1,4-diisocyanate;
p-phenylene diisothiocyanate;
xylylene-1,4-diisothiocyanate;
ethylidyne diisothiocyanate; or
a combination of two or more types among them.

Among these, from the viewpoint of polishing characteristic, mechanical strength, and other properties of the resulting polishing pad, it is preferable to use tolylene diisocyanate such as 2,6-tolylene diisocyanate (2,6-TDI) and 2,4-tolylene diisocyanate (2,4-TDI).

The content of the above polyisocyanate component relative to the entire isocyanate-terminated urethane prepolymer is preferably 20 to 50% by weight, more preferably 25 to 45% by weight, and most preferably 30 to 40% by weight.

### (Curing Agent)

Examples of the curing agent contained in the curable resin compositions include an amine curing agent, which will be described below.

Examples of the polyamine that constitutes the amine curing agent include a diamine, and examples thereof include an alkylenediamine such as ethylenediamine, propylenediamine, or hexamethylenediamine; a diamine having an aliphatic ring such as isophoronediamine or dicyclohexylmethane-4,4′-diamine; a diamine having an aromatic ring such as 3,3′-dichloro-4,4′-diaminodiphenylmethane (another name: methylenebis-o-chloroaniline) (hereinafter, abbreviated as MOCA); a diamine having a hydroxy group, in particular, a hydroxyalkylalkylenediamine, such as 2-hydroxyethylethylenediamine, 2-hydroxyethylpropylenediamine, di-2-hydroxyethylethylenediamine, di-2-hydroxyethylpropylenediamine, 2-hydroxypropylethylenediamine, or di-2-hydroxypropylethylenediamine; or a combination of two or more types among them. In addition, it is also possible to use a tri-functional triamine compound and a tetra- or higher-functional polyamine compound.

The particularly preferred curing agent is the above-mentioned MOCA, and it is also possible for the curing agent to consist of MOCA. The chemical structure of this MOCA is as follows.

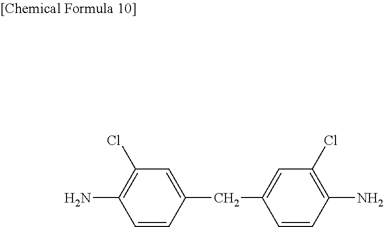 [SMILES: Nc1ccc(Cc2ccc(N)c(Cl)c2)cc1Cl]

As for the amount of e entire curing agent, an amount is used that provides a ratio of the number of moles of NH₂ in the curing agent to the number of moles of NCO in the isocyanate-terminated urethane prepolymer (number of moles of NH₂/number of moles of NCO) of preferably 0.7 to 1.1, more preferably 0.75 to 1.0, and most preferably 0.8 to 0.95.

### (Micro Hollow Spheres)

In the second embodiment, the curable resin composition can further contain a micro hollow sphere (micro hollow spheres).

By mixing the micro hollow spheres into the polyurethane resin, a foamed product can be formed. The micro hollow spheres refer to unfoamed thermoexpandable microspheres composed of an outer shell (polymer shell) composed of a thermoplastic resin and a low boiling point hydrocarbon encapsulated in the outer shell, and those formed by thermally expanding the unfoamed thermoexpandable microspheres. As the polymer shell, a thermoplastic resin such as an acrylonitrile-vinylidene chloride copolymer, an acrylonitrile-methyl methacrylate copolymer, or a vinyl chloride-ethylene copolymer can be used. Similarly, as the low boiling point hydrocarbon encapsulated in the polymer shell, for example, isobutane, pentane, isopentane, petroleum ether, or a combination of two or more types among them can be used.

### (Other Components)

In addition, it is also possible to add a catalyst or others commonly used in the art to the curable resin composition.

It is also possible to add the above-mentioned polyisocyanate component to the curable resin composition later, and the weight proportion of the additional polyisocyanate component relative to the total weight of the isocyanate-terminated urethane prepolymer and the additional polyisocyanate component is preferably 0.1 to 10% by weight, more preferably 0.5 to 8% by weight, and particularly preferably 1 to 5% by weight.

As the polyisocyanate component to be additionally added to the polyurethane resin curable composition, the above-mentioned polyisocyanate components can be used without particular limitation, but 4,4′-methylene-bis(cyclohexyl isocyanate)(hydrogenated MDI) is preferred.

In the second embodiment, the content of the carbonate group in the above polyol having a carbonate group in a molecule relative to the entire polishing layer of the polishing pad can be 0.5 to 6.4% by weight, 0.75 to 6.0% by weight, or 1.5 to 5.5% by weight.

The content of the carbonate group in the above polyol having a carbonate group in a molecule relative to the entire polishing layer of the polishing pad can be calculated based on the following expression (2).

$$\begin{matrix}[ Formula 2 ] & \\ content of carbonate group relative to entire polishing layer ( \% by weight ) = ( Wa \times Ra / 100 ) / Wb \times 100 & ( 2 )\end{matrix}$$

*Wa: weight of polyol having a carbonate group in a molecule
Ra: content of the carbonate group in the polyol having a carbonate group in a molecule (% by weight)
Wb: weight of polishing layer
*For example, in the case where the polishing layer is composed of the isocyanate-terminated urethane prepolymer, the curing agent, and the micro hollow spheres, the above Wb can be calculated as the total of the weight of the isocyanate-terminated urethane prepolymer (sum of the weight of the isocyanate component and the weight of the polyol component), the weight of the curing agent, and the weight of the micro hollow spheres.

### 2. Method for Polishing Surface of Optical Material or Semiconductor Material

In the second embodiment, the method for polishing the surface of an optical material or a semiconductor material includes a step of polishing the surface of an optical material or a semiconductor material using the above-mentioned polishing pad.

In the second embodiment, the method for polishing the surface of an optical material or a semiconductor material can further include a step of supplying slurry to the surface of the polishing pad, the surface of the optical material or the semiconductor material, or both of them.

### (Slurry)

The liquid component contained in the slurry is not particularly limited, examples of which include water (pure water), an acid, an alkali, an organic solvent, or a combination thereof, and it is selected according to the material of the workpiece to be polished, the desired polishing conditions, and other factors. It is preferable for the slurry to be composed mainly of water (pure water), and preferable to contain 80% by weight or more of water relative to the entire slurry. The abrasive grain component contained in the slurry is not particularly limited, examples of which include silica, zirconium silicate, cerium oxide, aluminum oxide, manganese oxide, or a combination thereof. The slurry may contain other components such as an organic matter that is soluble in the liquid component and a pH adjuster.

### Third Embodiment

### (Action)

As a result of diligent researches on the relationship between the type of polyol component that forms the isocyanate-terminated urethane prepolymer and the molecular weight distribution of the isocyanate-terminated urethane prepolymer and level difference resolving performance and defects, the present inventors have unexpectedly found that the use of a polyol having a carbonate group in a molecule and having a number average molecular weight of Mna as the high molecular weight polyol component that forms the isocyanate-terminated urethane prepolymer and the setting of the number average molecular weight of the isocyanate-terminated urethane prepolymer to not more than Mna can provide a polishing pad that can suppress dishing with excellent level difference resolving performance and can also suppress defects. The details of why such a characteristic is obtained are not clear, but are inferred as follows.

The polyol having a carbonate group in a molecule is considered to have lower crystallinity compared to PTMG since it has the carbonate group, and the isocyanate-terminated urethane prepolymer formed from such a polyol having a carbonate group in a molecule is also considered to have lower crystallinity. When the crystallinity of the isocyanate-terminated urethane prepolymer that forms the polishing layer is lowered, it is considered that scraps of the polishing layer generated during polishing are less likely to be aggregated to form large lumps. Also, when the number average molecular weight of the prepolymer is not more than Mna, it is considered that the content of an ultra-high molecular weight component, which will be described later, is small and the prepolymer has excellent uniformity, which thus allows the characteristics of the carbonate group to be expressed more prominently. As a result, it is inferred that dishing can be suppressed with improved level difference resolving performance and defects can also be suppressed in the workpiece to be polished.

### (Level Difference Resolving Performance)

The damascene process is known as a method for producing metal (Cu) wiring in the semiconductor manufacturing process. In this damascene process, grooves are dug in an insulating film on a silicon wafer, metal is embedded in these grooves by sputtering or other means, and excess metal is removed by chemical mechanical polishing (CMP) to form metal wiring. Usually, the insulating film is covered with a barrier metal before embedding the metal in order to resolve the physical or chemical stress occurring between the insulating film and the metal.

Schematic diagrams of an experiment to evaluate the level difference resolving performance are shown in FIG. 10 (a) to (c). FIG. 10(a) shows the state before initiating polishing. As shown in FIG. 10 (a), when a metal film (Cu film) 20 is embedded in a groove of an insulating film (oxide film) 10, a level difference depending on the width and depth of the groove (difference in thickness between the portion where the groove is not present and the portion where the groove is present) 40 occurs between the portion where the groove is present and the portion where the groove is not present, depending on the width of the groove that is present under the metal film 20. In FIG. 10 (a), the thickness 30 of the metal film 20 in the portion where the groove is not present is 800 Å, and the level difference 40 is 3500 Å. FIG. 10 (b) shows the state where the polishing amount is 2000 Å, and the level difference 41 is 2000 Å. FIG. 10 (c) shows the state where the polishing amount is 6000 Å, and the level difference 42 is almost 0.

In the third embodiment, the term “level difference resolving performance” refers to the performance of reducing level differences of patterned wafers having level differences (irregularities) as mentioned above when polishing is carried out.

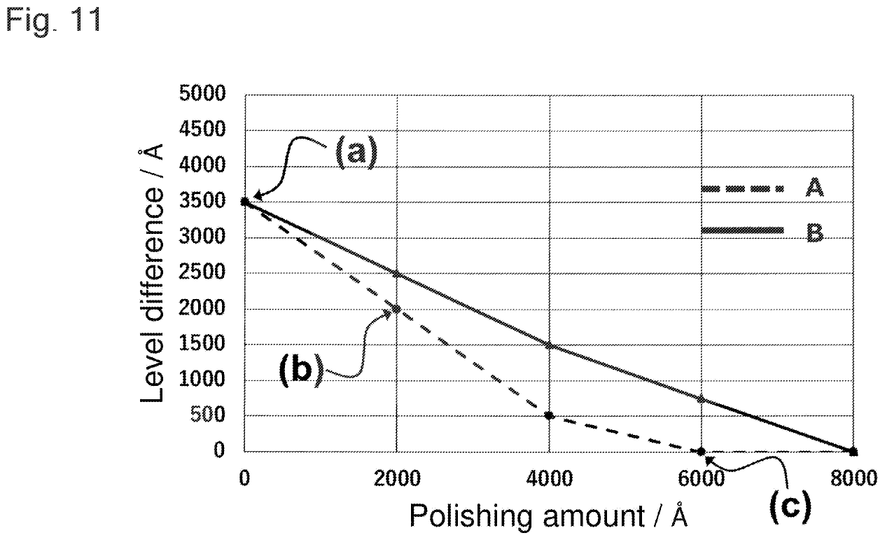

FIG. 11 shows a graph indicating the relationship between the polishing amount (Å) and the level difference (Å) in the case where polishing pad A with high level difference resolving performance (dotted line) and polishing pad B with relatively low level difference resolving performance (solid line) are used for a workpiece to be polished in the state of FIG. 10 (a). The locations marked with (a) to (c) regarding polishing pad A in FIG. 11 correspond to the states of FIG. 10 (a) to (c), respectively. In FIG. 11, although there is no difference in the level difference between the dotted line and the solid line at the time before initiating polishing (location of (a)), it is shown that polishing pad A (dotted line) results in a smaller level difference compared to polishing pad B (solid line) when polishing proceeds and the polishing amount is 2000 Å (location of (b)). Also, as can be seen from FIG. 11, polishing pad A (dotted line) resolves the level difference earlier compared to polishing pad B (solid line) (location of (c)). From the results of FIG. 11, it can be said that polishing pad A, shown by the dotted line, has relatively higher level difference resolving performance compared to polishing pad B, shown by the solid line.

### (Defects)

Also, in the third embodiment, the term “defects” means a generic term for defects including “particles”, which refer to residual fine particles that adhere to the surface of the workpiece to be polished, “pad scraps”, which refer to scraps of the polishing layer that adhere to the surface of the workpiece to be polished, “scratches”, which refer to scratches on the surface of the workpiece to be polished, and others, and the defect performance refers to the performance of reducing these “defects”.

Hereinafter, a polishing pad according to the third embodiment, a method for producing the polishing pad, and a method for polishing the surface of an optical material or a semiconductor material will be described.

### 1. Polishing Pad, Method for Producing Polishing Pad

In the third embodiment, the polishing pad is a polishing pad having a polishing layer including a polyurethane resin, in which the polyurethane resin is a cured product of a curable resin composition containing an isocyanate-terminated urethane prepolymer and a curing agent, and the isocyanate-terminated urethane prepolymer is a reaction product of a polyol component and a polyisocyanate component,
the polyol component includes a high molecular weight polyol, and the high molecular weight polyol includes a polyol having a carbonate group in a molecule and having a number average molecular weight of Mna, and
the number average molecular weight of the isocyanate-terminated urethane prepolymer is not more than Mna.

### (Polishing Pad)

The polishing pad according to the third embodiment has a polishing layer including a polyurethane resin. The polishing layer is disposed at a position in direct contact with a material to be polished, while other portions of the polishing pad may be constituted by a material for supporting the polishing pad, for example, a material that is rich in elasticity, such as rubber. Depending on the rigidity of the polishing pad, the polishing layer can be used as the polishing pad.

The polishing pad according to the third embodiment does not greatly differ in shape from general polishing pads except that it can suppress dissing and defects in the workpiece to be polished, and can be used in the same manner as general polishing pads. For example, it is possible to perform polishing by pressing the polishing layer against the material to be polished while rotating the polishing pad, or it is possible to perform polishing by pressing the material to be polished against the polishing layer while rotating the material to be polished.

The polishing pad according to the third embodiment can be created by generally known production methods such as mold molding and slab molding. It is produced as follows: at first, a block of polyurethane is formed by the above production methods, the block is formed into a sheet by slicing or other means, and a polishing layer formed from the polyurethane resin is molded and then pasted to a support or other material. Alternatively, the polishing layer can be molded directly on the support.

More specifically, the polishing layer becomes a polishing pad by attaching double-sided tape to the side opposite to the polishing surface of the polishing layer and cutting it into a predetermined shape. There is no particular restriction on the double-sided tape, and any double-sided tape known in the art can be arbitrarily selected for use. In addition, the polishing pad may have a single layer structure composed only of the polishing layer, or it may be composed of multiple layers with other layers (underlayer and support layer) pasted to the side opposite to the polishing surface of the polishing layer.

The polishing layer is molded by preparing a curable resin composition containing an isocyanate-terminated urethane prepolymer and a curing agent and curing the curable resin composition.

The polishing layer can be constituted by a foamed polyurethane resin, and foaming can be carried out by dispersing a foaming agent containing micro hollow spheres in the polyurethane resin. In this case, the polishing layer can be molded by preparing a curable resin composition containing an isocyanate-terminated urethane prepolymer, a curing agent, and a foaming agent, and foaming and curing the curable resin composition.

The curable resin composition can be, for example, a two-component composition prepared by mixing liquid A containing an isocyanate-terminated urethane prepolymer and liquid B containing a curing agent component. The other components may be added to liquid A or may be added to liquid B, but in the case where problems arise, it can be a composition constituted by further dividing the components into multiple liquids and mixing three or more liquids.

### (Isocyanate-Terminated Urethane Prepolymer)

In the third embodiment, the isocyanate-terminated urethane prepolymer is a product obtained by allowing the polyol component to react with the polyisocyanate component, the polyol component includes the high molecular weight polyol, and the high molecular weight polyol includes the above-mentioned polyol having a carbonate group in a molecule.

In the case where the number average molecular weight of the above-mentioned polyol having a carbonate group in a molecule is set to Mna, the number average molecular weight of the isocyanate-terminated urethane prepolymer is not more than Mna, and for example, in the case where Mna is 1000, it is 1000 or less, preferably 950 or less, and most preferably 90 or less. When the high molecular weight polyol includes the polyol having a carbonate group in a molecule and having a number average molecular weight of Mna and the number average molecular weight of the isocyanate-terminated urethane prepolymer is not more than Mna, it is possible to obtain a polishing pad that can suppress dishing with excellent level difference resolving performance and can also suppress defects.

The means for setting the number average molecular weight of the isocyanate-terminated urethane prepolymer to the above not more than Mna is not particularly limited, but it can be achieved by, for example, by reducing the content ratio of an ultra-high molecular weight component formed by adding three or more molecules of polyisocyanate component to two or more molecules of high molecular weight polyol included in a peak that is present in a molecular weight range of 700 to 10000, which will be described later, or by increasing the content ratio of a component that is included in a peak that is present in a molecular weight range of 400 to 7M), which will be described later. The means for reducing the content ratio of the above ultra-high molecular weight component relative to the entire isocyanate-terminated urethane prepolymer is not particularly limited, and examples thereof include using a high molecular weight polyol that is as uniform as possible (the width of molecular weight distribution is small) or setting the reaction conditions, such as temperature and pressure, to mild conditions to suppress chain-like generation of the ultra-high molecular weight component. The means for increasing the content ratio of a component that is included in a peak that is present in a molecular weight range of 400 to 700 relative to the entire isocyanate-terminated urethane prepolymer is not particularly limited, and examples thereof include adjusting the reaction conditions to increase the content ratio of a component formed by adding two molecules of polyisocyanate component to both ends of one molecule of low molecular weight polyol.

The number average molecular weight of the isocyanate-terminated urethane prepolymer can be 500 to 2500. The upper limit of the number average molecular weight of the isocyanate-terminated urethane prepolymer can be 3500 or less, 2500 or less, 2000 or less, 1500 or less, or 1000 or less, and the lower limit thereof can be 500 or more, 600 or more, 700 or more, or 800 or more. These upper limits and lower limits can be arbitrarily combined.

The weight average molecular weight of the isocyanate-terminated urethane prepolymer is preferably 500 to 2500, preferably 1000 to 2000, and most preferably 1300 to 1600.

In the third embodiment, the content ratio of a component that is included in a peak that is present in a molecular weight range of 200 to 400 relative to the entire isocyanate-terminated urethane prepolymer is preferably 10% or less, more preferably 8.5% or less, and most preferably 7% or less. The lower limit of the content ratio of a component that is included in such a peak can be 1% or more, 3% or more, or 5% or more, and these upper limits and lower limits can be arbitrarily combined. Also, it is preferable that the above peak that is present in a molecular weight range of 200 to 400 be an unreacted polyisocyanate component.

In the third embodiment, the content ratio of a component that is included in a peak that is present in a molecular weight range of 400 to 700 relative to the entire isocyanate-terminated urethane prepolymer is preferably 5 to 40%, more preferably 10 to 35%, and most preferably 15 to 30%. Also, it is preferable that the above peak that is present in a molecular weight range of 40) to 700 be derived from a component formed by adding two molecules of polyisocyanate component to both ends of one molecule of low molecular weight polyol.

In the third embodiment, the upper limit of the content ratio of a component that is included in a peak that is present in a molecular weight range of 700 to 10000 relative to the entire isocyanate-terminated urethane prepolymer is preferably 80% or less, more preferably 78% or less, and most preferably 76% or less. The lower limit of the content ratio of a component that is included in such a peak can be 50% or more, 60% or more, or 65% or more, and these upper limits and lower limits can be arbitrarily combined. Also, it is preferable that the above peak that is present in a molecular weight range of 700 to 10000 be derived from a component formed by adding two molecules of polyisocyanate component to both ends of one molecule of high molecular weight polyol, and an ultra-high molecular weight component formed by adding three or more molecules of polyisocyanate component to two or more molecules of high molecular weight polyol.

It is preferable that the above peak that is present in a molecular weight range of 700 to 10000 include an ultra-high molecular weight component formed by adding two or more molecules of high molecular weight polyol and three or more molecules of polyisocyanate component (in the case where the number average molecular weight Mna of the high molecular weight polyol is 1000, the molecular weight of the ultra-high molecular weight component will be 2000 or more). In the third embodiment, it is preferable that the amount of the above ultra-high molecular weight component be small. Since the above peak that is present in a molecular weight range of 700 to 1000 is broad, it is relatively difficult to identify the content ratio of the ultra-high molecular weight component. However, the content ratio of the ultra-high molecular weight component can be estimated by the number average molecular weight of the entire isocyanate-terminated prepolymer or the peak top molecular weight of the above peak that is present in a molecular weight range of 700 to 10000. As the number average molecular weight of the entire isocyanate-terminated prepolymer and/or the peak top molecular weight of the above peak that is present in a molecular weight range of 700 to 1000 is smaller, it can be estimated that the content ratio of the above ultra-high molecular weight component is smaller. In the third embodiment, it is preferable that the peak top molecular weight of the above peak that is present in a molecular weight region of 700 to 1000) be not more than Mna+1000 (Mna is the number average molecular weight of the above-mentioned polyol having a carbonate group in a molecule), and in the case where Mna is 1000, the peak top molecular weight is preferably 2000 or less, more preferably 1850 or less, and most preferably 1700 or less. In the case where Mna is 2000, the peak top molecular weight is preferably 3000 or less, more preferably 2850 or less, and most preferably 2700 or less. Also, as for the peak top molecular weight of the above peak that is present in a molecular weight range of 700 to 10000, the lower limit thereof can be 1000 or more, 1300 or more, or 1500 or more, and the upper limit thereof can be 3000 or less, 2850 or less, 2700 or less, 2000 or less, 1850 or less, or 1700 or less. These lower limits and upper limits can be arbitrarily combined. When the content of the above ultra-high molecular weight component is small, it is considered that the prepolymer has excellent uniformity, which thus allows the characteristics of the carbonate group to be expressed more prominently. As a result, it is inferred that dishing can be suppressed with improved level difference resolving performance and defects can also be suppressed in the workpiece to be polished.

The number average molecular weight and weight average molecular weight of the above-mentioned isocyanate-terminated urethane prepolymer, the content of a component that is included in each peak, and the number average molecular weight, weight average molecular weight, and peak top molecular weight of each peak can be calculated by preparing a sample and carrying out measurement based on the procedures described in (Method for preparing sample), (Measurement method), and (Measurement conditions) of (Gel permeation chromatography (GPC) measurement of isocyanate-terminated urethane prepolymer) in <Examples 1C to 3C, Comparative Examples 1C and 2C> in [Examples] described below.

The NCO equivalent (g/eq) of the isocyanate-terminated urethane prepolymer is preferably less than 600, more preferably 350 to 550, and most preferably 400 to 500. When the NCO equivalent (g/eq) is within the above numerical range, a polishing pad with moderate polishing performance can be obtained.

### (Polyol Component)

The above-mentioned polyol having a carbonate group in a molecule is one type of high molecular weight polyol.

It is preferable that the polyol having a carbonate group in a molecule include a structural unit derived from a polytetramethylene ether glycol. The number average molecular weight of the structural unit derived from the polytetramethylene ether glycol is preferably 100 to 1500, more preferably 150 to 1000, and most preferably 20M to 850.

It is preferable that the polyol having a carbonate group in a molecule include a polyether polycarbonate diol represented by the following formula (III), and it is more preferable that it consist of the polyether polycarbonate diol represented by the following formula (III):

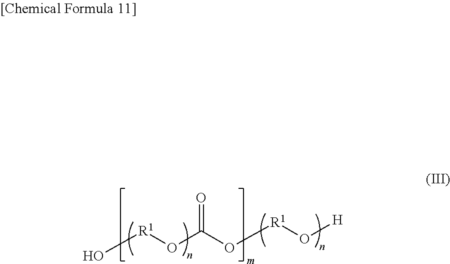

(in the above formula (III),
R¹ is a divalent hydrocarbon group having 2 to 10 carbon atoms, and a plurality of R is identical or different;
n is 2 to 30; and
m is 1 to 20.).

In the above formula (III) representing the above polyether polycarbonate diol, R¹ is a divalent hydrocarbon group having 2 to 10 carbon atoms, and examples of R¹ include ethylene, n-propylene, isopropylene, n-butylene, isobutylene, 1,1-dimethylethylene, n-pentylene, 2,2-dimethylpropylene, 2-methylbutylene, or a combination of two or more types among them. In particular, it is preferable that it be at least one selected from the group consisting of ethylene, isopropylene, and n-butylene. In the above formula (II), a plurality of R¹ is identical or different, but it is preferable that they be identical. Note that, when R¹ has 6 or more carbon atoms, such as n-hexene, the crystallinity of the polyether polycarbonate diol is increased, and the flexibility, elongation, and bendability of the resulting polishing pad at low temperatures will be deteriorated, which may be unfavorable. From such a viewpoint, R¹ is preferably a divalent hydrocarbon group having 2 to 5 carbon atoms.

In the above formula (III), n is 2 to 30, preferably 3 to 20, and more preferably 3 to 15.

In the above formula (III), m is 0.1 to 20, preferably 0.5 to 10, and more preferably 1 to 5.

In the case where the polyol having a carbonate group in a molecule includes the structural unit derived from the polytetramethylene ether glycol and also includes the polyether polycarbonate diol represented by the above formula (III), it is preferable that the structural unit derived from the polytetramethylene ether glycol be the moiety represented by —(R¹—O)ₙ— in the above formula (III).

The number average molecular weight (the above-mentioned Mna) of the polyol having a carbonate group in a molecule is preferably 200 to 5000, more preferably 500 to 3000, and most preferably 800 to 2500.

The number average molecular weight of the structural unit derived from the above polytetramethylene ether glycol and the number average molecular weight of the above-mentioned polyol having a carbonate group in a molecule can be calculated by carrying out measurement in the same manner as the procedures described in (Measurement method) and (Measurement conditions) of (Gel permeation chromatography (GPC) measurement of isocyanate-terminated urethane prepolymer) in <Examples 1C to 3C, Comparative Examples 1C and 2C> in [Examples] described below.

The content of the above polyol having a carbonate group in a molecule relative to the entire isocyanate-terminated urethane prepolymer is preferably 15 to 75% by weight, more preferably 20 to 65% by weight, and most preferably 20 to 60% by weight. When the content of the above polyol having a carbonate group in a molecule is within the above numerical range, it is possible to obtain a polishing pad that can suppress dishing with excellent level difference resolving performance and can also suppress defects.

Examples of the polyol component other than the above polyol having a carbonate group in a molecule included in the isocyanate-terminated urethane prepolymer include a low molecular weight polyol, a high molecular weight polyol other than the above polyol having a carbonate group in a molecule, or a combination thereof. In the third embodiment, the low molecular weight polyol is a polyol having a number average molecular weight of 30 to 300, and the high molecular weight polyol is a polyol having a number average molecular weight of greater than 300. The number average molecular weight of the above low molecular weight polyol and the high molecular weight polyol other than the above polyol having a carbonate group in a molecule can be calculated by carrying out measurement in the same manner as the procedures described in (Measurement method) and (Measurement conditions) of (Gel permeation chromatography (GPC) measurement of isocyanate-terminated urethane prepolymer) in <Examples 1C to 3C, Comparative Examples 1C and 2C> in [Examples] described below.

Examples of the above low molecular weight polyol include ethylene glycol, diethylene glycol, triethylene glycol, 1,2-propanediol, 1,3-propanediol, 1,3-butanediol, 1,4-butanediol, neopentyl glycol, pentanediol, 3-methyl-1,5-pentanediol, 1,6-hexanediol, or a combination of two or more types among them, and among them, diethylene glycol is preferred.

The content of the low molecular weight polyol relative to the entire isocyanate-terminated urethane prepolymer can be 0 to 20% by weight, 2 to 15% by weight, or 3 to 10% by weight. Alternatively, the content of the above low molecular weight polyol can be 0% by weight (the low molecular weight polyol is not included). In the third embodiment, the expression “not included” means that a component is not added intentionally, and does not exclude its inclusion as an impurity.

Examples of the high molecular weight polyol other than the above polyol having a carbonate group in a molecule include:
a polyether polyol such as polytetramethylene ether glycol (PTMG), polyethylene glycol, or polypropylene glycol;
a polyester polyol such as a reaction product of ethylene glycol and adipic acid or a reaction product of butylene glycol and adipic acid;
a polycarbonate polyol;
a polycaprolacton polyol; or
a combination of two or more types among them.

In the third embodiment, it is preferable that the high molecular weight polyol further include a polyether polyol.

The content of the high molecular weight polyol (including the above polyol having a carbonate group in a molecule) relative to the entire isocyanate-terminated urethane prepolymer is preferably 25 to 75% by weight, more preferably 35 to 65% by weight, and most preferably 40 to 60% by weight.

The content of the high molecular weight polyol other than the above polyol having a carbonate group in a molecule relative to the entire isocyanate-terminated urethane prepolymer is preferably 15 to 75% by weight, more preferably 20 to 65% by weight, and most preferably 25 to 60% by weight.

Also, it is possible for the above high molecular weight polyol to consist of the above polyol having a carbonate group in a molecule, or to consist of the above polyol having a carbonate group in a molecule and a polyether polyol.

### (Polyisocyanate Component)

Examples of the polyisocyanate component included in the isocyanate-terminated urethane prepolymer include:
m-phenylene diisocyanate;
p-phenylene diisocyanate;
2,6-tolylene diisocyanate (2,6-TDI);
2,4-tolylene diisocyanate (2,4-TDI);
naphthalene-1,4-diisocyanate;
diphenylmethane-4,4′-diisocyanate (MDI);
4,4′-methylene-bis(cyclohexyl isocyanate) (hydrogenated MDI);
3,3′-dimethoxy-4,4′-biphenyl diisocyanate;
3,3′-dimethyldiphenylmethane-4,4′-diisocyanate;
xylylene-1,4-diisocyanate;
4,4′-diphenylpropane diisocyanate
trimethylene diisocyanate;
hexamethylene diisocyanate;
propylene-1,2-diisocyanate;
butylene-1,2-diisocyanate;
cyclohexylene-1,2-diisocyanate;
cyclohexylene-1,4-diisocyanate;
p-phenylene diisothiocyanate;
xylylene-1,4-diisothiocyanate;
ethylidyne diisothiocyanate; or
a combination of two or more types among them.

Among these, from the viewpoint of polishing characteristic, mechanical strength, and other properties of the resulting polishing pad, it is preferable to use tolylene diisocyanate such as 2,6-tolylene diisocyanate (2,6-TDI) and 2,4-tolylene diisocyanate (2,4-TDI).

The content of the above polyisocyanate component relative to the entire isocyanate-terminated urethane prepolymer is preferably 20 to 50% by weight, more preferably 25 to 35% by weight, and most preferably 30 to 40% by weight.

### (Curing Agent)

Examples of the curing agent contained in the curable resin compositions include an amine curing agent, which will be described below.

Examples of the polyamine that constitutes the amine curing agent include a diamine, and examples thereof include an alkylenediamine such as ethylenediamine, propylenediamine, or hexamethylenediamine; a diamine having an aliphatic ring such as isophoronediamine or dicyclohexylmethane-4,4′-diamine; a diamine having an aromatic ring such as 3,3′-dichloro-4,4′-diaminodiphenylmethane (another name: methylenebis-o-chloroaniline) (hereinafter, abbreviated as MOCA); a diamine having a hydroxy group, in particular, a hydroxyalkylalkylenediamine, such as 2-hydroxyethylethylenediamine, 2-hydroxyethylpropylenediamine, di-2-hydroxyethylethylenediamine, di-2-hydroxyethylpropylenediamine, 2-hydroxypropylethylenediamine, or di-2-hydroxypropylethylenediamine; or a combination of two or more types among them. In addition, it is also possible to use a tri-functional triamine compound and a tetra- or higher-functional polyamine compound.

The particularly preferred curing agent is the above-mentioned MOCA, and it is also possible for the curing agent to consist of MOCA. The chemical structure of this MOCA is as follows.

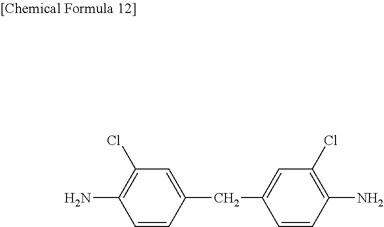 [SMILES: Nc1ccc(Cc2ccc(N)c(Cl)c2)cc1Cl]

As for the amount of the entire curing agent, an amount is used that provides a ratio of the number of moles of NH₂ in the curing agent to the number of moles of NCO in the isocyanate-terminated urethane prepolymer (number of moles of NH₂/number of moles of NCO) of preferably 0.7 to 1.1, more preferably 0.75 to 1.0, and most preferably 0.8 to 0.95.

### (Micro Hollow Spheres)

In the third embodiment, the curable resin composition can further contain a micro hollow sphere (micro hollow spheres).

By mixing the micro hollow spheres into the polyurethane resin, a foamed product can be formed. The micro hollow spheres refer to unfoamed thermoexpandable microspheres composed of an outer shell (polymer shell) composed of a thermoplastic resin and a low boiling point hydrocarbon encapsulated in the outer shell, and those formed by thermally expanding the unfoamed thermoexpandable microspheres. As the polymer shell, a thermoplastic resin such as an acrylonitrile-vinylidene chloride copolymer, an acrylonitrile-methyl methacrylate copolymer, or a vinyl chloride-ethylene copolymer can be used. Similarly, as the low boiling point hydrocarbon encapsulated in the polymer shell, for example, isobutane, pentane, isopentane, petroleum ether, or a combination of two or more types among them can be used.

### (Other Components)

In addition, it is also possible to add a catalyst or others commonly used in the art to the curable resin composition.

It is also possible to add the above-mentioned polyisocyanate component to the curable resin composition later, and the weight proportion of the additional polyisocyanate component relative to the total weight of the isocyanate-terminated urethane prepolymer and the additional polyisocyanate component is preferably 0.1 to 10% by weight, more preferably 0.5 to 8% by weight, and particularly preferably 1 to 5% by weight.

As the polyisocyanate component to be additionally added to the polyurethane resin curable composition, the above-mentioned polyisocyanate components can be used without particular limitation, but 4,4′-methylene-bis(cyclohexyl isocyanate)(hydrogenated MDI) is preferred.

### 2. Method for Polishing Surface of Optical Material or Semiconductor Material

In the third embodiment, the method for polishing the surface of an optical material or a semiconductor material includes a step of polishing the surface of an optical material or a semiconductor material using the above-mentioned polishing pad.

In the third embodiment, the method for polishing the surface of an optical material or a semiconductor material can further include a step of supplying slurry to the surface of the polishing pad, the surface of the optical material or the semiconductor material, or both of them.

### (Slurry)

The liquid component contained in the slurry is not particularly limited, examples of which include water (pure water), an acid, an alkali, an organic solvent, or a combination thereof, and it is selected according to the material of the workpiece to be polished, the desired polishing conditions, and other factors. It is preferable for the slurry to be composed mainly of water (pure water), and preferable to contain 80% by weight or more of water relative to the entire slurry. The abrasive grain component contained in the slurry is not particularly limited, examples of which include silica, zirconium silicate, cerium oxide, aluminum oxide, manganese oxide, or a combination thereof. The slurry may contain other components such as an organic matter that is soluble in the liquid component and a pH adjuster.

### EXAMPLES

The present invention will be described experimentally by means of the following examples, but the following description is not intended to be construed as limiting the scope of the present invention to the following examples.

### Examples 1A to 7A, Comparative Examples 1A to 3A

Examples 1A to 7A are Examples corresponding to the above-mentioned first embodiment.

### (Materials)

The materials used in Examples 1A to 7A and Comparative Examples 1A to 3A, described below, are listed below.

### Polyether Polycarbonate Diol (Used as a Raw Material for the Isocyanate-Terminated Urethane Prepolymer)

PEPCD (1) . . . Polyether polycarbonate diol (1) having a number average molecular weight of 1000, including a structural unit derived from a polytetramethylene ether glycol having a number average molecular weight of 250 (polyether polycarbonate diol where a plurality of R¹ is all n-butylene, n is 3.2, and m is 2.8 in the above formula (I). The details are shown in Table 1 below.)

PEPCD (2) to (4) . . . Polyether polycarbonate diols (2) to (4), respectively (similar to the above PEPCD (1), the details are shown in Table 1 below.)

### Isocyanate-Terminated Urethane Prepolymer:

Prepolymer (1) . . . Urethane prepolymer with an NCO equivalent of 420, including 43.8% by weight of 2,4-tolylene diisocyanate as the polyisocyanate component, and 50.4% by weight of a polyether polycarbonate diol represented by the above formula (I) having a number average molecular weight of 1000, including a structural unit derived from a polytetramethylene ether glycol having a number average molecular weight of 250, and 5.8% by weight of diethylene glycol as the polyol component
*The content (% by weight) of each component means the value in the case where the entire urethane prepolymer is 100% by weight. The same applies to prepolymers (2) to (4) below.

Prepolymer (2) . . . Urethane prepolymer with an NCO equivalent of 420, including 40.7% by weight of 2,4-tolylene diisocyanate as the polyisocyanate component, and 27.9% by weight of a polytetramethylene ether glycol having a number average molecular weight of 650, 27.9% by weight of a polytetramethylene ether glycol having a number average molecular weight of 1000, and 3.5% by weight of diethylene glycol as the polyol component

Prepolymer (3) . . . Urethane prepolymer with an NCO equivalent of 440, including 44.5% by weight of 2,4-tolylene diisocyanate as the polyisocyanate component, and 48.2% by weight of a polytetramethylene ether glycol having a number average molecular weight of 650 and 7.3% by weight of diethylene glycol as the polyol component

Prepolymer (4) . . . Urethane prepolymer with an NCO equivalent of 500, including 35.6% by weight of 2,4-tolylene diisocyanate as the polyisocyanate component, and 59.4% by weight of a polypropylene glycol having a number average molecular weight of 1000 and 5.0% by weight of diethylene glycol as the polyol component

Prepolymers (5) to (10) . . . The details are shown in Table 2 below.

The numerical value of each component shown in Table 2 means the parts by weight of each component in the case where the entire urethane prepolymer is 1000 parts by weight.

For example, prepolymer (5) shown in Table 2 is a urethane prepolymer with an NCO equivalent of 500, including 375 parts by weight of 2,4-tolylene diisocyanate as the polyisocyanate component, 562 parts by weight of the above-mentioned PEPCD (1) as the high molecular weight polyol component, and 63 parts by weight of diethylene glycol as the low molecular weight polyol component. The contents of 2,4-tolylene diisocyanate, PEPCD (1), and diethylene glycol are 37.5% by weight, 56.2% by weight, and 6.3% by weight, respectively, relative to the entire prepolymer (5).

TABLE 1

| | | PEPCD(1) | PEPCD(2) | PEPCD(3) | PEPCD(4) |
|---|---|---|---|---|---|
| Number average molecular | | 1000 | 1000 | 1000 | 2000 |
| weight of PEPCD | | | | | |
| Structural | Type | PTMG | PEG | PPG | PTMG |
| unit included | Number average | 250 | 250 | 250 | 650 |
| in PEPCD | molecular | | | | |
| | weight | | | | |
| R¹ | Type | n-Butylene | Ethylene | Isopropylene | n-Butylene |
| | Number of | 4 | 2 | 3 | 4 |
| | carbon atoms | | | | |

| | | | | |
|---|---|---|---|---|
| n | 3.2 | 5.3 | 4.0 | 8.8 |
| m | 2.8 | 2.8 | 2.8 | 2.0 |

*PEPCD: Polyether polycarbonate diol
PTMG: Polytetramethylene ether glycol
PEG: Polyethylene glycol
PPG: Polypropylene glycol

TABLE 2

| Prepolymer | | (5) | (6) | (7) | (8) | (9) | (10) |
|---|---|---|---|---|---|---|---|
| 2,4-TDI | Parts by weight | 375 | 353 | 414 | 401 | 401 | 358 |
| PEPCD | Parts by weight | 562 | 582 | 350 | 538 | 538 | 581 |
| | Type | PEPCD(1) | PEPCD(1) | PEPCD(1) | PEPCD(2) | PEPCD(3) | PEPCD(4) |
| PTMG650 | Parts by weight | 0 | 0 | 175 | 0 | 0 | 0 |
| DEG | Parts by weight | 63 | 65 | 61 | 61 | 61 | 61 |

| | | | | | | |
|---|---|---|---|---|---|---|
| NCO Equivalent | 500 | 600 | 420 | 420 | 420 | 420 |

*2,4-TDI: 2,4-Tolylene diisocyanate
PEPCD: Polyether polycarbonate diol
PTMG650: Polytetramethylene ether glycol having a number average molecular weight of 650
DEG: Diethylene glycol

### Curing Agent:

MOCA . . . 3,3′-Dichloro-4,4′-diaminodiphenylmethane (another name: methylenebis-o-chloroaniline)(NH₂ equivalent=133.5)

### Micro Hollow Spheres:

Expancel 461DU20 (manufactured by Japan Fillite Co., Ltd.)

Expancel 461DE20d70 (manufactured by Japan Fillite Co., Ltd.)

### Example 1A

100 g of prepolymer (1) as component A, 28.6 g of MOCA, which is a curing agent, as component B, and 3.0 g of micro hollow spheres (Expancel 461DU20) as component C were prepared. Note that, although each component is listed as a g indication to show the ratio thereof, it is only required to prepare the necessary weight (parts) depending on the size of the block. Hereinafter, the g (parts) indication will be used in the same manner.

Component A and component C were mixed, the mixture of component A and component C and component B were each defoamed under reduced pressure in advance, and then the mixture of component A and component C and component B were supplied to a mixing machine to obtain a mixed solution of component A, component B, and component C. Note that the ratio of the number of moles of NH₂ in MOCA of component B to the number of moles of NCO in prepolymer of component A (number of moles of NH₂/number of moles of NCO) in the obtained mixed solution of component A, component B, and component C is 0.90.

The obtained mixed solution of component A, component B, and component C was poured into a mold form (850 mm×850 mm square shape) that had been heated to 80° C., and allowed to undergo primary curing at 80° C. for 30 minutes. The formed resin foamed product was removed from the mold form and allowed to undergo secondary curing in an oven at 120° C. for 4 hours. The obtained resin foamed product was allowed to cool down to 25° C. and then heated again in an oven at 120° C. for 5 hours. The obtained resin foamed product was sliced into thickness of 1.3 mm over the thickness direction to create a urethane sheet, and double-sided tape was attached to the back side of this urethane sheet to obtain a polishing pad.

### Example 2A

A urethane sheet was created in the same manner as in Example 1A to obtain a polishing pad, except that 100 g of prepolymer (5) as component A and 24.0 g of MOCA as component B were prepared instead of 100 g of prepolymer (1) as component A and 28.6 g of MOCA as component B in Example 1A.

Note that the ratio of the number of moles of NH₂ in MOCA of component B to the number of moles of NCO in prepolymer of component A (number of moles of NH₂/number of moles of NCO) in the mixed solution of component A, component B, and component C is 0.90.

### Example 3A

A urethane sheet was created in the same manner as in Example 1A to obtain a polishing pad, except that 100 g of prepolymer (6) as component A and 20.0 g of MOCA as component B were prepared instead of 100 g of prepolymer (1) as component A and 28.6 g of MOCA as component B in Example 1A.

Note that the ratio of the number of moles of NH₂ in MOCA of component B to the number of moles of NCO in prepolymer of component A (number of moles of NH₂/number of moles of NCO) in the mixed solution of component A, component B, and component C is 0.90.

### Example 4A

A urethane sheet was created in the same manner as in Example 1A to obtain a polishing pad, except that 100 g of prepolymer (7) as component A was prepared instead of 100 g of prepolymer (1) as component A in Example 1A.

Note that the ratio of the number of moles of NH₂ in MOCA of component B to the number of moles of NCO in prepolymer of component A (number of moles of NH₂/number of moles of NCO) in the mixed solution of component A, component B, and component C is 0.90.

### Example 5A

A urethane sheet was created in the same manner as in Example 1A to obtain a polishing pad, except that 100 g of prepolymer (8) as component A was prepared instead of 100 g of prepolymer (1) as component A in Example 1A.

Note that the ratio of the number of moles of NH₂ in MOCA of component B to the number of moles of NCO in prepolymer of component A (number of moles of NH₂/number of moles of NCO) in the mixed solution of component A, component B, and component C is 0.90.

### Example 6A

A urethane sheet was created in the same manner as in Example 1A to obtain a polishing pad, except that 100 g of prepolymer (9) as component A was prepared instead of 100 g of prepolymer (1) as component A in Example 1A.

Note that the ratio of the number of moles of NH₂ in MOCA of component B to the number of moles of NCO in prepolymer of component A (number of moles of NH₂/number of moles of NCO) in the mixed solution of component A, component B, and component C is 0.90.

### Example 7A

A urethane sheet was created in the same manner as in Example 1A to obtain a polishing pad, except that 100 g of prepolymer (10) as component A was prepared instead of 100 g of prepolymer (1) as component A in Example 1A.

Note that the ratio of the number of moles of NH₂ in MOCA of component B to the number of moles of NCO in prepolymer of component A (number of moles of NH₂/number of moles of NCO) in the mixed solution of component A, component B, and component C is 0.90.

### Comparative Example 1A

A urethane sheet was created in the same manner as in Example 1A to obtain a polishing pad, except that 100 g of prepolymer (2) as component A was prepared instead of 100 g of prepolymer (I) as component A in Example 1A.

Note that the ratio of the number of moles of NH₂ in MOCA of component B to the number of moles of NCO in prepolymer of component A (number of moles of NH₂/number of moles of NCO) in the mixed solution of component A, component B, and component C is 0.90.

### Comparative Example 2A

A urethane sheet was created in the same manner as in Example 1A to obtain a polishing pad, except that 100 g of prepolymer (3) as component A and 27.3 g of MOCA, which is a curing agent, as component B were prepared instead of 100 g of prepolymer (1) as component A and 28.6 g of MOCA as component B in Example 1A.

Note that the ratio of the number of moles of NH₂ in MOCA of component B to the number of moles of NCO in prepolymer of component A (number of moles of NH₂/number of moles of NCO) in the mixed solution of component A, component B, and component C is 0.90.

### Comparative Example 3A

A urethane sheet was created in the same manner as in Example 1A to obtain a polishing pad, except that 100 g of prepolymer (4) as component A, 24.0 g of MOCA, which is a curing agent, as component B, and 2.5 g of micro hollow spheres (Expancel 461DE20d70) as component C were prepared instead of 100 g of prepolymer (1) as component A, 28.6 g of MOCA as component B, and 3.0 g of micro hollow spheres (Expancel 461DU20) as component C in Example 1A.

Note that the ratio of the number of moles of NH₂ in MOCA of component B to the number of moles of NCO in prepolymer of component A (number of moles of NH₂/number of moles of NCO) in the mixed solution of component A, component B, and component C is 0.90.

### (Evaluation Methods)

For each of the urethane sheets (in the state before attaching the double-sided tape) or polishing pads of Examples 1A and 4A and Comparative Examples 1A to 3A, the following measurements were carried out: (1) thickness, density, D hardness, tensile strength, and tear strength, (2) defects, and (3) polishing rate. In addition, for each of the urethane sheets (before attaching the double-sided tape) of Examples 2 Å, 3 Å, and 5A to 7 Å, the following measurements were carried out: (1) thickness, density, D hardness, tensile strength, and tear strength. The measurement results are shown in Tables 3 to 8 and FIGS. 1 to 4 below.

### (1) Thickness, Density, D Hardness, Tensile Strength, and Tear Strength

### (Thickness)

The thickness (mm) of the urethane sheet was measured in accordance with the Japanese Industrial Standard (JIS K 6550).

### (Density)

The density (g/cm³) of the urethane sheet was measured in accordance with the Japanese Industrial Standard (JIS K 6505).

### (D Hardness)

The D hardness of the urethane sheet was measured using a D hardness meter in accordance with the Japanese Industrial Standards (JIS-K-6253). Here, the measurement sample was obtained by stacking multiple urethane sheets as necessary such that the total thickness was at least 4.5 mm or more.

(Tensile Strength) The urethane sheet was cut into the form of a dumbbell as specified in the Japanese Industrial Standard (JIS 6550) for measuring the tensile strength, and the tensile strength (kg/mm²) was measured in accordance with the Japanese Industrial Standard (JIS 6550) at a tensile speed of 100 mm/min and a test temperature of 20° C.

### (Tear Strength)

The urethane sheet was cut into the shape of a rectangle having a notch as specified in the Japanese Industrial Standard (JIS 6550) for measuring the tear strength, and the tear strength (kg/mm²) was measured in accordance with the Japanese Industrial Standard (JIS 6550) at a tear speed of 100 mm/min and a test temperature of 20° C.

### (2) Defects

The polishing pad was installed at a predetermined position of a polishing apparatus via double-sided tape having an acrylic adhesive, and the polishing processing was performed under the polishing conditions below.

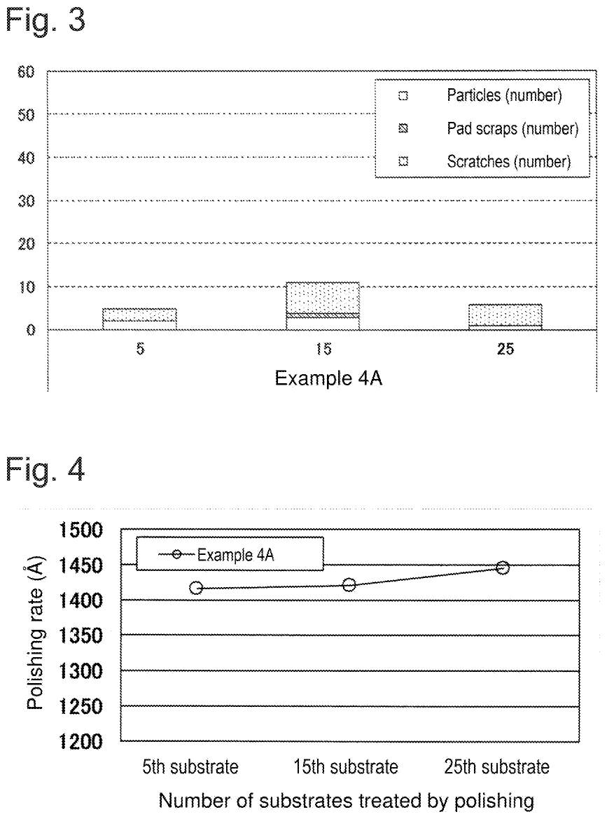

Then, defects (surface defects) with a size of 90 nm or more were detected using the high sensitivity measurement mode of a surface inspection apparatus (manufactured by KLA-Tencor Corporation, Surfscan SP2XP) for the 5th, 15th, and 25th substrates treated by polishing. For each of the detected defects, analysis of SEM images taken using a review SEM (manufactured by KLA-Tencor Corporation, eDR-5210) with measurement mode: ELECTRON_OPTICS and measurement conditions: ELECTRON_LANDING_ENERGY 300 eV and BEAM CURRENT 100 pA was carried out, and the number of each from the categories of “particles”, “pad scraps”, and “scratches” was measured. The results are shown in Tables 5 and 6 and FIGS. 1 and 3.

It can be said that the fewer the number of “particles”, “pad scraps”, and “scratches”, the fewer the number of defects and the better.

### <Conditions of Polishing Test>

Polishing machine used: manufactured by EBARA CORPORATION, F-REX300X
Disk: 3MA188 (#100)
Rotation speed: (turn table) 85 rpm, (top ring) 86 rpm
Polishing pressure: 3.5 psi
Polishing agent: manufactured by Fujimi Incorporated, part number: PL6115 (weight ratio of PL6115 undiluted solution:pure water=1:1 mixed solution)
Temperature of polishing agent: 20° C.
Discharge amount of polishing agent: 200 ml/min
Workpiece used (workpiece to be polished): substrate on which an insulating film of tetraethoxysilane was formed on a 12-inch silicon wafer by PE-CVD to a thickness of 1 μm.
Pad break: 35N 10 minutes
Conditioning: Ex-situ, 35N, 4 scans
Number of substrates treated by polishing: 25

### (3) Polishing Rate

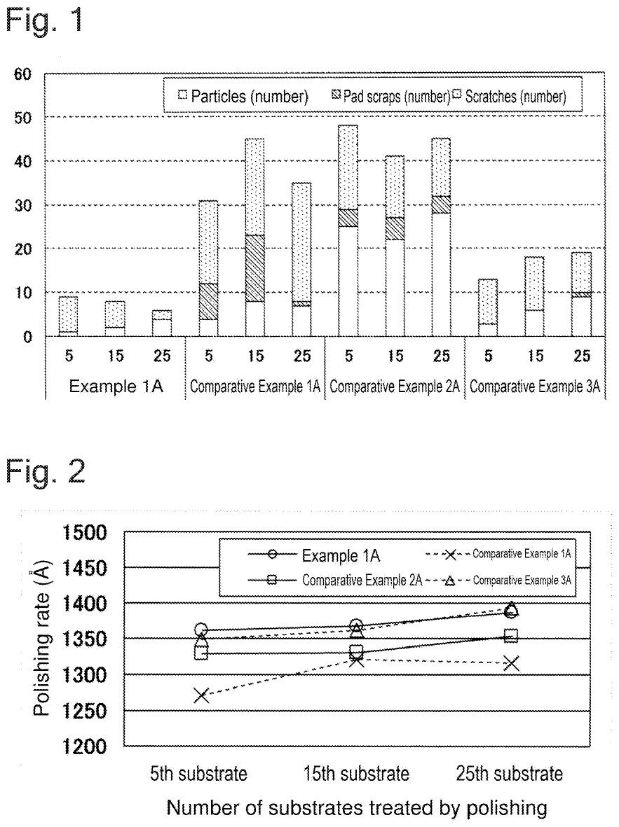

The polishing pad was installed at a predetermined position of a polishing apparatus via double-sided tape having an acrylic adhesive, and the polishing processing was performed under the polishing conditions of the above “(2) Defects”. Then, the polishing rate (unit: Å) for the 5th, 15th, and 25th substrates treated by polishing was measured. The results are shown in Tables 7 and 8 and FIGS. 2 and 4.

TABLE 3

| | | | | Tensile | Tear |
|---|---|---|---|---|---|
| | Thickness | Density | D | strength | strength |
| | (mm) | (g/cm³) | Hardness | (kg/mm²) | (kg/mm²) |
| Example 1A | 1.302 | 0.778 | 59.5 | 2.21 | 1.10 |
| Comparative | 1.309 | 0.783 | 62.0 | 2.35 | 1.36 |
| Example 1A | | | | | |
| Comparative | 1.299 | 0.788 | 60.0 | 2.35 | 1.25 |
| Example 2A | | | | | |
| Comparative | 1.297 | 0.786 | 52.0 | 1.61 | 1.01 |
| Example 3A | | | | | |

TABLE 4

| | | | | Tensile | Tear |
|---|---|---|---|---|---|
| | Thickness | Density | D | strength | strength |
| | (mm) | (g/cm³) | Hardness | (kg/mm²) | (kg/mm²) |
| Example 2A | 1.301 | 0.833 | 53.0 | 1.94 | 1.05 |
| Example 3A | 1.310 | 0.863 | 47.0 | 1.88 | 1.06 |
| Example 4A | 1.302 | 0.778 | 60.0 | 2.23 | 1.24 |
| Example 5A | 1.296 | 0.786 | 61.0 | 2.18 | 1.13 |
| Example 6A | 1.309 | 0.783 | 62.0 | 2.22 | 1.12 |
| Example 7A | 1.296 | 0.797 | 62.5 | 2.03 | 1.08 |

TABLE 5

| | | | | Comparative | | | Comparative | | | Comparative | | |
|---|---|---|---|---|---|---|---|---|---|---|---|---|
| | Example 1A | | | Example 1A | | | Example 2A | | | Example 3A | | |
| Number of | 5 | 15 | 25 | 5 | 15 | 25 | 5 | 15 | 25 | 5 | 15 | 25 |
| substrates | | | | | | | | | | | | |
| treated by | | | | | | | | | | | | |
| polishing | | | | | | | | | | | | |
| Particles | 1 | 2 | 4 | 4 | 8 | 7 | 25 | 22 | 28 | 3 | 6 | 9 |
| (number) | | | | | | | | | | | | |
| Pad scraps | 0 | 0 | 0 | 8 | 15 | 1 | 4 | 5 | 4 | 0 | 0 | 1 |
| (number) | | | | | | | | | | | | |
| Scratches | 8 | 6 | 2 | 19 | 22 | 27 | 19 | 14 | 13 | 10 | 12 | 9 |
| (number) | | | | | | | | | | | | |

TABLE 6

| | Example | | |
|---|---|---|---|
| | 4A | | |
| Number of substrates | 5 | 15 | 25 |
| treated by polishing | | | |
| Particles (number) | 2 | 3 | 1 |
| Pad scraps (number) | 0 | 1 | 0 |
| Scratches (number) | 3 | 7 | 5 |

TABLE 7

| | Polishing rate (Å) | | |
|---|---|---|---|
| | 5th | 15th | 25th |
| | substrate | substrate | substrate |
| Example 1A | 1361 | 1369 | 1388 |
| Comparative Example 1A | 1270 | 1321 | 1317 |
| Comparative Example 2A | 1329 | 1330 | 1354 |
| Comparative Example 3A | 1349 | 1362 | 1394 |

TABLE 8

Polishing rate (Å)

| | 5th substrate | 15th substrate | 25th substrate |
|---|---|---|---|
| Example 4A | 1417 | 1421 | 1446 |

From the results of Tables 5 and 6 and FIGS. 1 and 3, it was found that the polishing pads of Examples 1A and 4A, which used urethane prepolymers including a polyether polycarbonate diol, had very few defects compared to the polishing pads of Comparative Examples 1A and 2A, which used urethane prepolymers including a polytetramethylene ether glycol, and to the polishing pad of Comparative Example 3A, which used a urethane prepolymer including a polypropylene glycol, and that the occurrence of defects can be suppressed. In particular, the polishing pads of Examples 1A and 4A were found to be extremely superior in terms of defect suppression, as no defects with respect to pad scraps were observed regardless of the number of substrates treated by polishing, unlike the polishing pads of Comparative Examples 1 to 3.

Also, it was found from the results of Tables 7 and 8 and FIGS. 2 and 4 that the polishing pads of Examples 1A and 4A are excellent in polishing properties, with polishing rates equal to or higher than those of the polishing pads of Comparative Examples 1A to 3A.

From the above, it was found that a polishing pad formed using an isocyanate-terminated urethane prepolymer including a polyether polycarbonate diol represented by the above formula (I) can suppress the occurrence of defects at the time of polishing and also exhibits an excellent polishing rate.

### Examples 1B to 15B, Comparative Examples 1B to 7B

Examples 1B to 15B are Examples corresponding to the above-mentioned second embodiment.

### (Materials)

The materials used in Examples 1B to 15B and Comparative Examples 1B to 7B, described below, are listed below.

### Polyol Having a Carbonate Group in a Molecule (Used as a Raw Material for the Isocyanate-Terminated Urethane Prepolymer)

PEPCD (1) . . . Polyether polycarbonate diol having a number average molecular weight of 1000, including a structural unit derived from a polytetramethylene ether glycol having a number average molecular weight of 250 (This corresponds to a polyether polycarbonate diol where a plurality of R¹ is all n-butylene, n is 3.2, and m is 2.8 in the above formula (II), and the content of the carbonate group relative to the entire polyether polycarbonate diol, as calculated based on expression (1) described in the above second embodiment, is 17.0% by weight. The details are shown in Table 9 below.)

PEPCD (2) to (I1) . . . Polyether polycarbonate diols (2) to (I1), respectively (similar to the above PEPCD (1), the details are shown in Table 9 below.)

### Isocyanate-Terminated Urethane Prepolymer

Prepolymers (1) to (22) . . . The details are shown in Table 10 below.

The numerical value of each component shown in Table 10 means the parts by weight of each component in the case where the entire urethane prepolymer is 1000 parts by weight.

For example, prepolymer (1) shown in Table 10 is a urethane prepolymer with an NCO equivalent of 500, including 388 parts by weight of 2,4-tolylene diisocyanate as the polyisocyanate component, 367 parts by weight of the above-mentioned PEPCD (1) and 184 parts by weight of a polytetramethylene ether glycol having a number average molecular weight of 650 as the high molecular weight polyol component, and 61 parts by weight of diethylene glycol as the low molecular weight polyol component. The contents of 2,4-tolylene diisocyanate, PEPCD (1), the polytetramethylene ether glycol having a number average molecular weight of 650, and diethylene glycol are 38.8% by weight, 36.7% by weight, 18.4% by weight, and 6.1% by weight, respectively, relative to the entire prepolymer (1).

TABLE 9

| | | PEPCD(1) | PEPCD(2) | PEPCD(3) | PEPCD(4) | PEPCD(5) | PEPCD(6) |
|---|---|---|---|---|---|---|---|
| Number average molecular | | 1000 | 1000 | 1000 | 1000 | 1000 | 1000 |
| weight of PEPCD | | | | | | | |
| Structural unit | Type | PTMG | PEG | PPG | PTMG | PEG | PPG |
| included in | Number average | 250 | 250 | 250 | 650 | 650 | 650 |
| PEPCD | molecular weight | | | | | | |
| R¹ | Type | n-Butylene | Ethylene | Isopropylene | n-Butylene | Ethylene | Isopropylene |
| | Number of | 4 | 2 | 3 | 4 | 2 | 3 |
| | carbon atom | | | | | | |

| | | | | | | |
|---|---|---|---|---|---|---|
| n | 3.2 | 5.3 | 4.0 | 8.8 | 14.4 | 10.9 |
| m | 2.8 | 2.8 | 2.8 | 0.5 | 0.5 | 0.5 |
| Content of carbonate | 17.0 | 17.0 | 17.0 | 3.2 | 3.2 | 3.2 |
| group (% by weight) | | | | | | |

| | | PEPCD(7) | PEPCD(8) | PEPCD(9) | PEPCD(10) | PEPCD(11) |
|---|---|---|---|---|---|---|
| Number average molecular | | 2000 | 2000 | 2000 | 2000 | 4000 |
| weight of PEPCD | | | | | | |
| Structural unit | Type | PTMG | PTMG | PTMG | PTMG | PTMG |
| included in | Number average | 250 | 650 | 1000 | 1600 | 250 |
| PEPCD | molecular weight | | | | | |
| R¹ | Type | n-Butylene | n-Butylene | n-Butylene | n-Butylene | n-Butylene |
| | Number of | 4 | 4 | 4 | 4 | 4 |
| | carbon atom | | | | | |

| | | | | | |
|---|---|---|---|---|---|
| n | 3.2 | 8.8 | 13.6 | 22.0 | 3.2 |
| m | 6.6 | 2.0 | 1.0 | 0.2 | 14.2 |
| Content of carbonate | 19.9 | 6.1 | 3.0 | 0.7 | 21.3 |
| group (% by weight) | | | | | |

*PEPCD: Polyether polycarbonate diol
PTMG: Polytetramethylene ether glycol
PEG: Polyethylene glycol
PPG: Polypropylene glycol

TABLE 10

| Prepolymer | | (1) | (2) | (3) | (4) | (5) | (6) |
|---|---|---|---|---|---|---|---|
| 2,4-TDI | Parts by weight | 388 | 388 | 388 | 388 | 388 | 388 |
| PEPCD | Parts by weight | 367 | 367 | 367 | 367 | 367 | 367 |
| | Type | PEPCD(1) | PEPCD(2) | PEPCD(3) | PEPCD(4) | PEPCD(5) | PEPCD(6) |
| PTMG650 | Parts by weight | 184 | 184 | 184 | 184 | 184 | 184 |
| DEG | Parts by weight | 61 | 61 | 61 | 61 | 61 | 61 |

| | | | | | | |
|---|---|---|---|---|---|---|
| NCO Equivalent | 500 | 500 | 500 | 500 | 500 | 500 |

| Prepolymer | | (7) | (8) | (9) | (10) | (11) |
|---|---|---|---|---|---|---|
| 2,4-TDI | Parts by weight | 363 | 363 | 363 | 414 | 393 |
| PEPCD | Parts by weight | 382 | 382 | 382 | 350 | 362 |
| | Type | PEPCD(7) | PEPCD(8) | PEPCD(9) | PEPCD(1) | PEPCD(8) |
| PTMG650 | Parts by weight | 191 | 191 | 191 | 175 | 181 |
| DEG | Parts by weight | 64 | 64 | 64 | 61 | 64 |

| | | | | | |
|---|---|---|---|---|---|
| NCO Equivalent | 500 | 500 | 500 | 420 | 420 |

| Prepolymer | | (12) | (13) | (14) | (15) | (16) | (17) |
|---|---|---|---|---|---|---|---|
| 2,4-TDI | Parts by weight | 366 | 340 | 375 | 337 | 363 | 350 |
| PEPCD | Parts by weight | 380 | 396 | 563 | 597 | 382 | 390 |
| | Type | PEPCD(1) | PEPCD(8) | PEPCD(4) | PEPCD(8) | PEPCD(10) | PEPCD(11) |
| PTMG650 | Parts by weight | 190 | 198 | 0 | 0 | 191 | 195 |
| DEG | Parts by weight | 64 | 66 | 63 | 66 | 64 | 65 |

| | | | | | | |
|---|---|---|---|---|---|---|
| NCO Equivalent | 600 | 600 | 500 | 500 | 500 | 500 |

| Prepolymer | | (18) | (19) | (20) | (21) | (22) |
|---|---|---|---|---|---|---|
| 2,4-TDI | Parts by weight | 412 | 393 | 340 | 438 | 392 |
| PEPCD | Parts by weight | 0 | 362 | 396 | 0 | 0 |
| | Type | — | PEPCD(10) | PEPCD(10) | — | — |
| PTMG650 | Parts by weight | 529 | 181 | 198 | 504 | 547 |
| DEG | Parts by weight | 59 | 64 | 66 | 58 | 61 |

| | | | | | |
|---|---|---|---|---|---|
| NCO Equivalent | 500 | 420 | 600 | 420 | 600 |

*2,4-TDI: 2,4-Tolylene diisocyanate
PEPCD: Polyether polycarbonate diol
PTMG650: Polytetramethylene ether glycol having a number average molecular weight of 650
DEG: Diethylene glycol

### Curing Agent:

MOCA . . . 3,3′-Dichloro-4,4′-diaminodiphenylmethane (another name: methylenebis-o-chloroaniline)(MOCA)(NH₂ equivalent=133.5)

### Micro Hollow Spheres:

Expancel 461DU20 (manufactured by Japan Fillite Co., Ltd.)

### Example 1B

1000 g of prepolymer (1) as component A, 240 g of MOCA, which is a curing agent, as component B, and 30 g of micro hollow spheres (Expancel 461DU20) as component C were prepared. Note that, although each component is listed as a g indication to show the ratio thereof, it is only required to prepare the necessary weight (parts) depending on the size of the block. Hereinafter, the g (parts) indication will be used in the same manner.

Component A and component C were mixed, and the obtained mixture of component A and component C was defoamed under reduced pressure. Component B was also defoamed under reduced pressure. The defoamed mixture of component A and component C and the defoamed component B were supplied to a mixing machine to obtain a mixed solution of component A, component B, and component C. Note that the ratio of the number of moles of NH₂ in MOCA of component B to the number of moles of NCO in prepolymer of component A (number of moles of NH₂/number of moles of NCO) in the obtained mixed solution of component A, component B, and component C is 0.9.

The obtained mixed solution of component A, component B, and component C was poured into a mold form (850 mm×850 mm square shape) that had been heated to 80° C., and allowed to undergo primary curing at 80° C. for 30 minutes. The formed resin foamed product was removed from the mold form and allowed to undergo secondary curing in an oven at 120° C. for 4 hours. The obtained resin foamed product was allowed to cool down to 25° C. and then heated again in an oven at 120° C. for 5 hours. The obtained resin foamed product was sliced into thickness of 1.3 mm over the thickness direction to create a urethane sheet, and double-sided tape was attached to the back side of this urethane sheet to obtain a polishing pad.

The content of the carbonate group in the polyol having a carbonate group in a molecule relative to the entire polishing layer was calculated based on expression (2) described in the above second embodiment to be 4.93% by weight.

### Example 2B

A urethane sheet was created in the same manner as in Example 1B to obtain a polishing pad, except that 1000 g of prepolymer (2) as component A was used instead of 1000 g of prepolymer (1) as component A in Example 1B.

Note that the ratio of the number of moles of NH₂ in MOCA of component B to the number of moles of NCO in prepolymer of component A (number of moles of NH₂/number of moles of NCO) in the mixed solution of component A, component B, and component C is 0.9. Also, the content of the carbonate group in the polyol having a carbonate group in a molecule relative to the entire polishing layer was calculated based on the above-mentioned expression (2) to be 4.93% by weight.

### Example 3B

A urethane sheet was created in the same manner as in Example 1B to obtain a polishing pad, except that 1000 g of prepolymer (3) as component A was used instead of 1000 g of prepolymer (1) as component A in Example 1B.

Note that the ratio of the number of moles of NH₂ in MOCA of component B to the number of moles of NCO in prepolymer of component A (number of moles of NH₂/number of moles of NCO) in the mixed solution of component A, component B, and component C is 0.9. Also, the content of the carbonate group in the polyol having a carbonate group in a molecule relative to the entire polishing layer was calculated based on the above-mentioned expression (2) to be 4.93% by weight.

### Example 4B

A urethane sheet was created in the same manner as in Example 1B to obtain a polishing pad, except that 1000 g of prepolymer (4) as component A was used instead of 1000 g of prepolymer (1) as component A in Example 1B.

Note that the ratio of the number of moles of NH₂ in MOCA of component B to the number of moles of NCO in prepolymer of component A (number of moles of NH₂/number of moles of NCO) in the mixed solution of component A, component B, and component C is 0.9. Also, the content of the carbonate group in the polyol having a carbonate group in a molecule relative to the entire polishing layer was calculated based on the above-mentioned expression (2) to be 0.91% by weight.

### Example 5B

A urethane sheet was created in the same manner as in Example 1B to obtain a polishing pad, except that 1000 g of prepolymer (5) as component A was used instead of 1000 g of prepolymer (1) as component A in Example 1B.

Note that the ratio of the number of moles of NH₂ in MOCA of component B to the number of moles of NCO in prepolymer of component A (number of moles of NH₂/number of moles of NCO) in the mixed solution of component A, component B, and component C is 0.9. Also, the content of the carbonate group in the polyol having a carbonate group in a molecule relative to the entire polishing layer was calculated based on the above-mentioned expression (2) to be 0.91% by weight.

### Example 6B

A urethane sheet was created in the same manner as in Example 1B to obtain a polishing pad, except that 1000 g of prepolymer (6) as component A was used instead of 1000 g of prepolymer (1) as component A in Example 1B.

Note that the ratio of the number of moles of NH₂ in MOCA of component B to the number of moles of NCO in prepolymer of component A (number of moles of NH₂/number of moles of NCO) in the mixed solution of component A, component B, and component C is 0.9. Also, the content of the carbonate group in the polyol having a carbonate group in a molecule relative to the entire polishing layer was calculated based on the above-mentioned expression (2) to be 0.91% by weight.

### Example 7B

A urethane sheet was created in the same manner as in Example 1B to obtain a polishing pad, except that 1000 g of prepolymer (7) as component A was used instead of 1000 g of prepolymer (1) as component A in Example 1B.

Note that the ratio of the number of moles of NH₂ in MOCA of component B to the number of moles of NCO in prepolymer of component A (number of moles of NH₂/number of moles of NCO) in the mixed solution of component A, component B, and component C is 0.9. Also, the content of the carbonate group in the polyol having a carbonate group in a molecule relative to the entire polishing layer was calculated based on the above-mentioned expression (2) to be 5.98% by weight.

### Example 8B

A urethane sheet was created in the same manner as in Example 1B to obtain a polishing pad, except that 1000 g of prepolymer (8) as component A was used instead of 1000 g of prepolymer (1) as component A in Example 1B.

Note that the ratio of the number of moles of NH₂ in MOCA of component B to the number of moles of NCO in prepolymer of component A (number of moles of NH₂/number of moles of NCO) in the mixed solution of component A, component B, and component C is 0.9. Also, the content of the carbonate group in the polyol having a carbonate group in a molecule relative to the entire polishing layer was calculated based on the above-mentioned expression (2) to be 1.83% by weight.

### Example 9B

A urethane sheet was created in the same manner as in Example 1B to obtain a polishing pad, except that 1000 g of prepolymer (9) as component A was used instead of 1000 g of prepolymer (1) as component A in Example 1B.

Note that the ratio of the number of moles of NH₂ in MOCA of component B to the number of moles of NCO in prepolymer of component A (number of moles of NH₂/number of moles of NCO) in the mixed solution of component A, component B, and component C is 0.9. Also, the content of the carbonate group in the polyol having a carbonate group in a molecule relative to the entire polishing layer was calculated based on the above-mentioned expression (2) to be 0.89% by weight.

### Example 10B

A urethane sheet was created in the same manner as in Example 1B to obtain a polishing pad, except that 1000 g of prepolymer (10) as component A was used instead of 1000 g of prepolymer (1) as component A in Example 1B and the amount of MOCA used as component B was changed from 240 g to 286 g.

Note that the ratio of the number of moles of NH₂ in MOCA of component B to the number of moles of NCO in prepolymer of component A (number of moles of NH₂/number of moles of NCO) in the mixed solution of component A, component B, and component C is 0.9. Also, the content of the carbonate group in the polyol having a carbonate group in a molecule relative to the entire polishing layer was calculated based on the above-mentioned expression (2) to be 4.53% by weight.

### Example 11B

A urethane sheet was created in the same manner as in Example 1B to obtain a polishing pad, except that 1000 g of prepolymer (11) as component A was used instead of 1000 g of prepolymer (1) as component A in Example 1B and the amount of MOCA used as component B was changed from 240 g to 286 g.

Note that the ratio of the number of moles of NH₂ in MOCA of component B to the number of moles of NCO in prepolymer of component A (number of moles of NH₂/number of moles of NCO) in the mixed solution of component A, component B, and component C is 0.9. Also, the content of the carbonate group in the polyol having a carbonate group in a molecule relative to the entire polishing layer was calculated based on the above-mentioned expression (2) to be 1.68% by weight.

### Example 12B

A urethane sheet was created in the same manner as in Example 1B to obtain a polishing pad, except that 1000 g of prepolymer (12) as component A was used instead of 1000 g of prepolymer (1) as component A in Example 1B and the amount of MOCA used as component B was changed from 240 g to 200 g.

Note that the ratio of the number of moles of NH₂ in MOCA of component B to the number of moles of NCO in prepolymer of component A (number of moles of NH₂/number of moles of NCO) in the mixed solution of component A, component B, and component C is 0.9. Also, the content of the carbonate group in the polyol having a carbonate group in a molecule relative to the entire polishing layer was calculated based on the above-mentioned expression (2) to be 5.27% by weight.

### Example 13B

A urethane sheet was created in the same manner as in Example 1B to obtain a polishing pad, except that 1000 g of prepolymer (13) as component A was used instead of 1000 g of prepolymer (1) as component A in Example 1B and the amount of MOCA used as component B was changed from 240 g to 200 g.

Note that the ratio of the number of moles of NH₂ in MOCA of component B to the number of moles of NCO in prepolymer of component A (number of moles of NH₂/number of moles of NCO) in the mixed solution of component A, component B, and component C is 0.9. Also, the content of the carbonate group in the polyol having a carbonate group in a molecule relative to the entire polishing layer was calculated based on the above-mentioned expression (2) to be 1.96% by weight.

### Example 14B

A urethane sheet was created in the same manner as in Example 1B to obtain a polishing pad, except that 1000 g of prepolymer (14) as component A was used instead of 1000 g of prepolymer (1) as component A in Example 1B.

Note that the ratio of the number of moles of NH₂ in MOCA of component B to the number of moles of NCO in prepolymer of component A (number of moles of NH₂/number of moles of NCO) in the mixed solution of component A, component B, and component C is 0.9. Also, the content of the carbonate group in the polyol having a carbonate group in a molecule relative to the entire polishing layer was calculated based on the above-mentioned expression (2) to be 1.40% by weight.

### Example 15B

A urethane sheet was created in the same manner as in Example 1B to obtain a polishing pad, except that 1000 g of prepolymer (15) as component A was used instead of 1000 g of prepolymer (1) as component A in Example 1B.

Note that the ratio of the number of moles of NH₂ in MOCA of component B to the number of moles of NCO in prepolymer of component A (number of moles of NH₂/number of moles of NCO) in the mixed solution of component A, component B, and component C is 0.9. Also, the content of the carbonate group in the polyol having a carbonate group in a molecule relative to the entire polishing layer was calculated based on the above-mentioned expression (2) to be 2.87% by weight.

### Comparative Example 1B

A urethane sheet was created in the same manner as in Example 1B to obtain a polishing pad, except that 1000 g of prepolymer (16) as component A was used instead of 1000 g of prepolymer (1) as component A in Example 1B.

Note that the ratio of the number of moles of NH₂ in MOCA of component B to the number of moles of NCO in prepolymer of component A (number of moles of NH₂/number of moles of NCO) in the mixed solution of component A, component B, and component C is 0.9. Also, the content of the carbonate group in the polyol having a carbonate group in a molecule relative to the entire polishing layer was calculated based on the above-mentioned expression (2) to be 0.22% by weight.

### Comparative Example 2B

A urethane sheet was created in the same manner as in Example 1B to obtain a polishing pad, except that 1000 g of prepolymer (17) as component A was used instead of 1000 g of prepolymer (1) as component A in Example 1B.

Note that the ratio of the number of moles of NH₂ in MOCA of component B to the number of moles of NCO in prepolymer of component A (number of moles of NH₂/number of moles of NCO) in the mixed solution of component A, component B, and component C is 0.9. Also, the content of the carbonate group in the polyol having a carbonate group in a molecule relative to the entire polishing layer was calculated based on the above-mentioned expression (2) to be 6.54% by weight.

### Comparative Example 3B

A urethane sheet was created in the same manner as in Example 1B to obtain a polishing pad, except that 1000 g of prepolymer (18) as component A was used instead of 1000 g of prepolymer (1) as component A in Example 1B.

Note that the ratio of the number of moles of NH₂ in MOCA of component B to the number of moles of NCO in prepolymer of component A (number of moles of NH₂/number of moles of NCO) in the mixed solution of component A, component B, and component C is 0.9. Also, the content of the carbonate group in the polyol having a carbonate group in a molecule relative to the entire polishing layer was calculated based on the above-mentioned expression (2) to be 0% by weight (no carbonate group was included in the polishing layer).

### Comparative Example 4B

A urethane sheet was created in the same manner as in Example 1B to obtain a polishing pad, except that 1000 g of prepolymer (19) as component A was used instead of 1000 g of prepolymer (1) as component A in Example 1B and the amount of MOCA used as component B was changed from 240 g to 286 g.

Note that the ratio of the number of moles of NH₂ in MOCA of component B to the number of moles of NCO in prepolymer of component A (number of moles of NH₂/number of moles of NCO) in the mixed solution of component A, component B, and component C is 0.9. Also, the content of the carbonate group in the polyol having a carbonate group in a molecule relative to the entire polishing layer was calculated based on the above-mentioned expression (2) to be 0.20% by weight.

### Comparative Example 5B

A urethane sheet was created in the same manner as in Example 1B to obtain a polishing pad, except that 1000 g of prepolymer (20) as component A was used instead of 1000 g of prepolymer (1) as component A in Example 1B and the amount of MOCA used as component B was changed from 240 g to 200 g.

Note that the ratio of the number of moles of NH₂ in MOCA of component B to the number of moles of NCO in prepolymer of component A (number of moles of NH₂/number of moles of NCO) in the mixed solution of component A, component B, and component C is 0.9. Also, the content of the carbonate group in the polyol having a carbonate group in a molecule relative to the entire polishing layer was calculated based on the above-mentioned expression (2) to be 0.24% by weight.

### Comparative Example 6B

A urethane sheet was created in the same manner as in Example 1B to obtain a polishing pad, except that 1000 g of prepolymer (21) as component A was used instead of 1000 g of prepolymer (1) as component A in Example 1B and the amount of MOCA used as component B was changed from 240 g to 286 g.

Note that the ratio of the number of moles of NH₂ in MOCA of component B to the number of moles of NCO in prepolymer of component A (number of moles of NH₂/number of moles of NCO) in the mixed solution of component A, component B, and component C is 0.9. Also, the content of the carbonate group in the polyol having a carbonate group in a molecule relative to the entire polishing layer was calculated based on the above-mentioned expression (2) to be 0% by weight (no carbonate group was included in the polishing layer).

### Comparative Example 7B

A urethane sheet was created in the same manner as in Example 1B to obtain a polishing pad, except that 1000 g of prepolymer (22) as component A was used instead of 1000 g of prepolymer (1) as component A in Example 1B and the amount of MOCA used as component B was changed from 240 g to 200 g.

Note that the ratio of the number of moles of NH₂ in MOCA of component B to the number of moles of NCO in prepolymer of component A (number of moles of NH₂/number of moles of NCO) in the mixed solution of component A, component B, and component C is 0.9. Also, the content of the carbonate group in the polyol having a carbonate group in a molecule relative to the entire polishing layer was calculated based on the above-mentioned expression (2) to be 0% by weight (no carbonate group was included in the polishing layer).

### Comparative Example 8B

As Comparative Example 8B, 1C1000 (manufactured by Nitta Haas Incorporated), which is a conventionally known polishing pad, was prepared.

### (Evaluation Methods)

For each of the polishing pads of Examples 1B and 10B and Comparative Examples 1B and 8B, the following evaluations were carried out: (1) level difference resolving performance and (2) defects.

### (1) Level Difference Resolving Performance

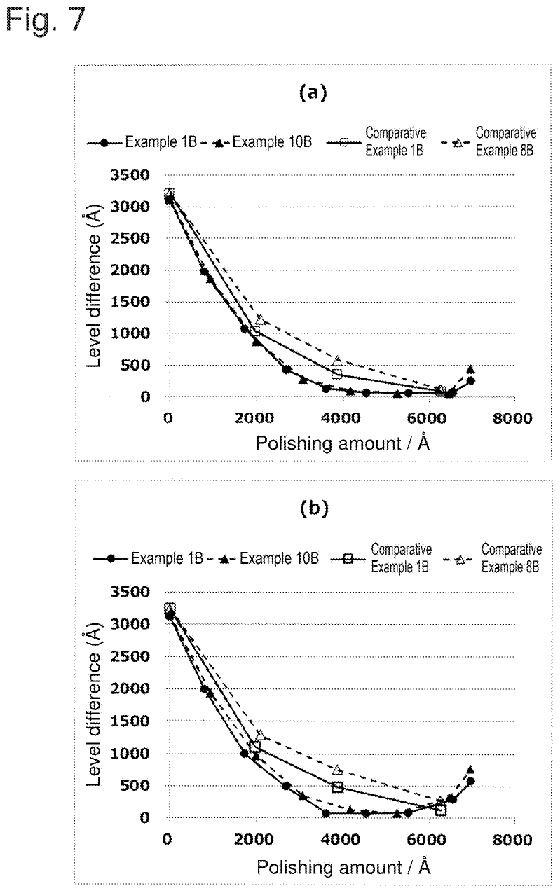

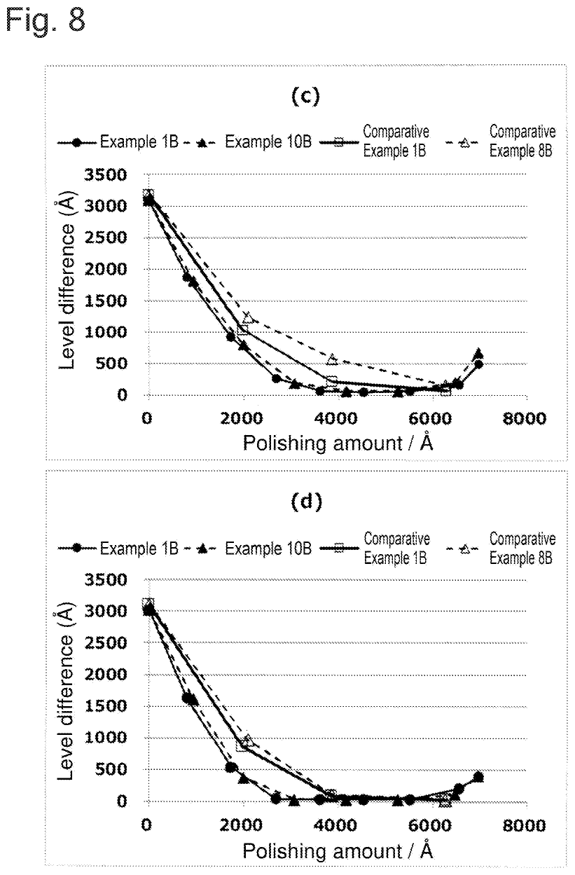

Each polishing pad was installed at a predetermined position of a polishing apparatus via double-sided tape having an acrylic adhesive, and the polishing processing was performed under the conditions shown in <Polishing conditions> below. Then, after the polishing processing, the level difference resolving performance was evaluated by measuring with a micro-shape measuring apparatus (manufactured by KLA Tencor Corporation, P-16+OF). The evaluation results for each polishing pad are shown in Table 11 and FIGS. 7 and 8.

### <Measurement Procedures and Conditions>

In the present Examples and Comparative Examples, each polishing pad was used for patterned wafers (insulating film: Si(OC₂H₅)₄ film) having a Cu film thickness of about 7000 Å and level differences of 3000 to 3300 Å and having different wiring widths, and polishing was performed adjusting the polishing rate such that the polishing amount at one time was about 1000 Å to carry out the polishing in stages, with a level difference measurement on the wafers performed at each stage. The level difference measurement was carried out on the portion of each wiring width on the patterned wafers.

The graph of FIG. 7 (a) shows the results in the case of polishing wiring with a Cu wiring width of 120 μm and an insulating film width of 120 μm, the graph of FIG. 7 (b) shows the results in the case of polishing wiring with a Cu wiring width of 100 μm and an insulating film width of 100 μm, the graph of FIG. 8 (c) shows the results in the case of polishing wiring with a Cu wiring width of 50 μm and an insulating film width of 50 μm, and the graph of FIG. 8 (d) shows the wiring with a Cu wiring width of 10 μm and an insulating film width of 10 μm. The smaller the value of wiring width, the finer the wiring.

### <Polishing Conditions>

Polishing machine used: F-REX300X (manufactured by EBARA CORPORATION)
Disk: A188 (manufactured by 3M Company)
Temperature of polishing agent: 20° C.
Rotation speed of polishing turn table: 90 rpm
Rotation speed of polishing head: 81 rpm
Polishing pressure: 3.5 psi
Polishing slurry: CSL-9044C (a mixed solution with a weight ratio of CSL-9044C undiluted solution:pure water=1:9 was used)(manufactured by FUJIFILM Planar Solutions, LLC)
Flow rate of polishing slurry: 200 ml/min
Polishing time: 60 seconds
Workpiece to be polished: (level difference resolving performance) each patterned wafer mentioned above, (defects) Cu film substrate
Pad break: 32N 10 minutes
Conditioning: in-situ 18N 16 scans, Ex-situ 35N 4 scans

### (2) Defects

Each polishing pad was installed at a predetermined position of a polishing apparatus via double-sided tape having an acrylic adhesive, and the polishing processing was performed on a Cu film substrate (12-inch diameter disk) under the conditions shown in the above-mentioned <Polishing conditions> of (1) Level difference resolving performance.

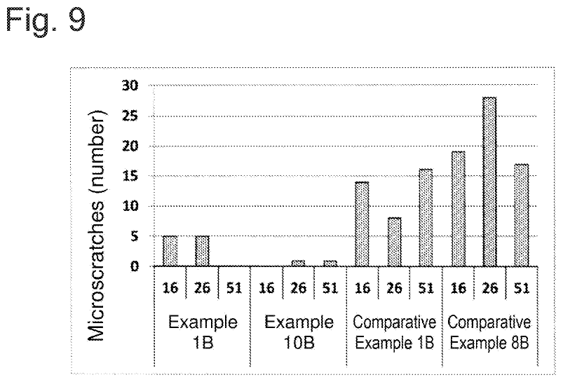

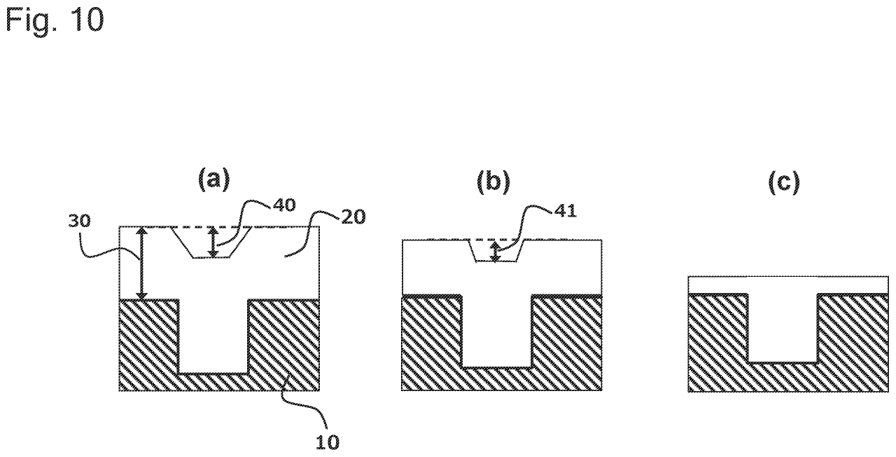

The 16th, 26th, and 51st Cu film substrates treated by polishing were measured with the high sensitivity measurement mode of a surface inspection apparatus (manufactured by KLA-Tencor Corporation, Surfscan SP2XP), and the number of microscratches (scratches in the form of fine dents of 0.2 μm or more and 10 μm or less) on the entire substrate surface was observed, the total of which was then determined. The evaluation results are shown in Table 12 and FIG. 9.

It can be said that, when the number of microscratches is 5 or less, the number of defects is small, which is good.

TABLE 11

Polishing amount (Å)

| | | | 0 | 802 | 1739 | 2698 | 3632 | 4557 | 5529 | 6570 | 6992 |
|---|---|---|---|---|---|---|---|---|---|---|---|
| Example | Level | (a) | 3096 | 1971 | 1068 | 426 | 128 | 60 | 59 | 72 | 246 |
| 1B | difference | (b) | 3117 | 1989 | 990 | 482 | 71 | 72 | 81 | 289 | 573 |
| | (Å) | (c) | 3074 | 1872 | 911 | 262 | 59 | 48 | 60 | 159 | 483 |
| | | (d) | 3007 | 1620 | 531 | 34 | 27 | 29 | 26 | 199 | 383 |

| | | | Polishing amount (Å) | | | | | | | |
|---|---|---|---|---|---|---|---|---|---|---|
| | | | 0 | 934 | 1995 | 3085 | 4181 | 5281 | 6474 | 6975 |
| Example | Level | (a) | 3107 | 1874 | 876 | 282 | 96 | 62 | 64 | 447 |
| 10B | difference | (b) | 3139 | 1938 | 976 | 346 | 126 | 75 | 317 | 762 |
| | (Å) | (c) | 3092 | 1808 | 794 | 185 | 62 | 61 | 195 | 674 |
| | | (d) | 3019 | 1601 | 370 | 29 | 28 | 29 | 108 | 402 |

Polishing amount (Å)

| | | | 0 | 1980 | 3875 | 6287 |
|---|---|---|---|---|---|---|
| Comparative | Level | (a) | 3203 | 1030 | 355 | 86 |
| Example | difference | (b) | 3234 | 1098 | 481 | 131 |
| 1B | (Å) | (c) | 3185 | 1026 | 207 | 73 |
| | | (d) | 3110 | 857 | 88 | 27 |

Polishing amount (Å)

| | | | 0 | 2094 | 3876 | 6283 |
|---|---|---|---|---|---|---|
| | Level | (a) | 3203 | 1218 | 580 | 122 |
| Comparative | difference | (b) | 3234 | 1285 | 749 | 268 |
| Example | (Å) | (c) | 3185 | 1234 | 570 | 150 |
| 8B | | (d) | 3110 | 960 | 100 | 30 |

* (a) to (d) in Table 11 indicate the following.
(a): Polishing of wiring portion with a Cu wiring width of 120 μm and an insulating film width of 120 μm on the patterned wafer
(b): Polishing of wiring portion with a Cu wiring width of 100 μm and an insulating film width of 100 μm on the patterned wafer
(c): Polishing of wiring portion with a Cu wiring width of 50 μm and an insulating film width of 50 μm on the patterned wafer
(d): Polishing of wiring portion with a Cu wiring width of 10 μm and an insulating film width of 10 μm on the patterned wafer

TABLE 12

| | | | | | | | Comparative | | | Comparative | | |
|---|---|---|---|---|---|---|---|---|---|---|---|---|
| | Example 1B | | | Example 10B | | | Example 1B | | | Example 10B | | |
| Number of | 16 | 26 | 51 | 16 | 26 | 51 | 16 | 26 | 51 | 16 | 26 | 51 |
| substrates | | | | | | | | | | | | |
| treated by | | | | | | | | | | | | |
| polishing | | | | | | | | | | | | |
| Micro- | 5 | 5 | 0 | 0 | 1 | 1 | 14 | 8 | 16 | 19 | 28 | 17 |
| scratches | | | | | | | | | | | | |
| (number) | | | | | | | | | | | | |

The polishing pads of Examples 1B to 15B relate to urethane prepolymers using polyols with a carbonate group content of 1.5 to 21.0% by weight. On the other hand, the polishing pads of Comparative Examples 1B, 2B, 4B, and 5B each relate to a urethane prepolymer using a polyol with a carbonate group content of less than 1.5% by weight or greater than 21.0% by weight, and the polishing pads of Comparative Examples 3B, 6B, and 7B relate to urethane prepolymers not using a polyol having a carbonate group. Also, Comparative Example 8B is a conventionally known polishing pad.

From the results of Tables 11 and 12 and FIGS. 7 to 9, it was found that the polishing pads of Examples 1B and 10B have superior level difference resolving performance in all wiring widths compared to the polishing pads of Comparative Examples 1B and 8B, and that scratches are significantly decreased and the occurrence of defects can be suppressed. In addition, the polishing pad of Comparative Example 2B had poor flexibility, elongation, and bendability at low temperatures, making it not suited for polishing.

From the above, it was found that a polishing pad formed from a urethane prepolymer using a polyol having a carbonate group in a molecule with a carbonate group content of 1.5 to 21.0% by weight can suppress dishing at the time of polishing (excellent in level difference resolving performance) and can also suppress the occurrence of defects.

### Examples 1C to 3C, Comparative Examples 1C and 2C

Examples 1C to 3C are Examples corresponding to the above-mentioned third embodiment.

### (Materials)

The materials used in Examples 1C to 3C and Comparative Examples 1C and 2C, described below, are listed below.

### Polyol Having a Carbonate Group in a Molecule (Used as a Raw Material for the

Isocyanate-Terminated Urethane Prepolymer) PEPCD (1) . . . Polyether polycarbonate diol having a number average molecular weight of 1000, including a structural unit derived from a polytetramethylene ether glycol having a number average molecular weight of 250 (This corresponds to a polyether polycarbonate diol where a plurality of R¹ is all n-butylene, n is 3.2, and m is 2.8 in the above formula (III).)

PEPCD (2) . . . Polyether polycarbonate diol having a number average molecular weight of 2000, including a structural unit derived from a polytetramethylene ether glycol having a number average molecular weight of 650 (This corresponds to a polyether polycarbonate diol where a plurality of R¹ is all n-butylene, n is 8.8, and m is 2.0 in the above formula (III).)

### Isocyanate-Terminated Urethane Prepolymer

Prepolymer (1) . . . Urethane prepolymer with an NCO equivalent of 420, including 414 parts by weight of 2,4-tolylene diisocyanate as the polyisocyanate component, 350 parts by weight of the above-mentioned PEPCD (1) and 175 parts by weight of a polytetramethylene ether glycol having a number average molecular weight of 650 as the high molecular weight polyol component, and 61 parts by weight of diethylene glycol as the low molecular weight polyol component.

Prepolymer (2) . . . Urethane prepolymer with an NCO equivalent of 460, including 400 parts by weight of 2,4-tolylene diisocyanate as the polyisocyanate component, 360 parts by weight of the above-mentioned PEPCD (1) and 179 parts by weight of a polytetramethylene ether glycol having a number average molecular weight of 650 as the high molecular weight polyol component, and 61 parts by weight of diethylene glycol as the low molecular weight polyol component.

Prepolymer (3) . . . Urethane prepolymer with an NCO equivalent of 420, including 393 parts by weight of 2,4-tolylene diisocyanate as the polyisocyanate component, 362 parts by weight of the above-mentioned PEPCD (2) and 181 parts by weight of a polytetramethylene ether glycol having a number average molecular weight of 650 as the high molecular weight polyol component, and 64 parts by weight of diethylene glycol as the low molecular weight polyol component.

ADIPRENE L325 . . . Trade name of urethane prepolymer manufactured by Uniroyal Chemical Corporation (urethane prepolymer with an NCO equivalent of 460, including 2,4-tolylene diisocyanate and 4,4′-methylenebis(cyclohexyl isocyanate) (hydrogenated MDI) as the polyisocyanate component, a polytetramethylene ether glycol as the high molecular weight polyol component, and diethylene glycol as the low molecular weight polyol component)

DC6912 . . . Trade name of urethane prepolymer manufactured by Tosoh Corporation (urethane prepolymer with an NCO equivalent of 540, including 2,4-tolylene diisocyanate as the polyisocyanate component, a polytetramethylene ether glycol as the high molecular weight polyol component, and diethylene glycol as the low molecular weight polyol component)

### Curing Agent:

MOCA . . . 3,3′-Dichloro-4,4′-diaminodiphenylmethane (another name: methylenebis-o-chloroaniline)(MOCA)(NH₂ equivalent=133.5)

### Micro Hollow Spheres:

Expancel 461DU20 (manufactured by Japan Fillite Co., Ltd.)

### Example 1C

1000 g of prepolymer (1) as component A, 286 g of MOCA, which is a curing agent, as component B, and 30 g of micro hollow spheres (Expancel 461DU20) as component C were prepared. Note that, although each component is listed as a g indication to show the ratio thereof, it is only required to prepare the necessary weight (parts) depending on the size of the block. Hereinafter, the g (parts) indication will be used in the same manner.

Component A and component C were mixed, and the obtained mixture of component A and component C was defoamed under reduced pressure. Component B was also defoamed under reduced pressure. The defoamed mixture of component A and component C and the defoamed component B were supplied to a mixing machine to obtain a mixed solution of component A, component B, and component C. Note that the ratio of the number of moles of NH₂ in MOCA of component B to the number of moles of NCO in prepolymer of component A (number of moles of NH₂/number of moles of NCO) in the obtained mixed solution of component A, component B, and component C is 0.9.

The obtained mixed solution of component A, component B, and component C was poured into a mold form (850 mm×850 mm square shape) that had been heated to 80° C., and allowed to undergo primary curing at 80° C. for 30 minutes. The formed resin foamed product was removed from the mold form and allowed to undergo secondary curing in an oven at 120° C. for 4 hours. The obtained resin foamed product was allowed to cool down to 25° C. and then heated again in an oven at 120° C. for 5 hours. The obtained resin foamed product was sliced into thickness of 1.3 mm over the thickness direction to create a urethane sheet, and double-sided tape was attached to the back side of this urethane sheet to obtain a polishing pad.

### Example 2C

A urethane sheet was created in the same manner as in Example 1C to obtain a polishing pad, except that 1000 g of prepolymer (2) as component A was used instead of 1000 g of prepolymer (1) as component A in Example 1C and the content of MOCA as component B was changed from 286 g to 261 g.

Note that the ratio of the number of moles of NH₂ in MOCA of component B to the number of moles of NCO in prepolymer of component A (number of moles of NH₂/number of moles of NCO) in the mixed solution of component A, component B, and component C is 0.9.

### Example 3C

A urethane sheet was created in the same manner as in Example 1C to obtain a polishing pad, except that 1000 g of prepolymer (3) as component A was used instead of 1000 g of prepolymer (1) as component A in Example 1C.

Note that the ratio of the number of moles of NH₂ in MOCA of component B to the number of moles of NCO in prepolymer of component A (number of moles of NH₂/number of moles of NCO) in the mixed solution of component A, component B, and component C is 0.9.

### Comparative Example 1C

A urethane sheet was created in the same manner as in Example 1C to obtain a polishing pad, except that 1000 g of ADIPRENE L325 as component A was used instead of 1000 g of prepolymer (1) as component A in Example 1C and the content of MOCA as component B was changed from 286 g to 261 g.

Note that the ratio of the number of moles of NH₂ in MOCA of component B to the number of moles of NCO in prepolymer of component A (number of moles of NH₂/number of moles of NCO) in the mixed solution of component A, component B, and component C is 0.9.

### Comparative Example 2C

A urethane sheet was created in the same manner as in Example 1C to obtain a polishing pad, except that 1000 g of DC6912 as component A was used instead of 1000 g of prepolymer (1) as component A in Example 1C and the content of MOCA as component B was changed from 286 g to 223 g.

Note that the ratio of the number of moles of NH₂ in MOCA of component B to the number of moles of NCO in prepolymer of component A (number of moles of NH₂/number of moles of NCO) in the mixed solution of component A, component B, and component C is 0.9.

### (Gel Permeation Chromatography (GPC) Measurement of Isocyanate-Terminated Urethane Prepolymer)

### (Method for Preparing Sample)

5 g of each of the isocyanate-terminated urethane prepolymers used in Examples 1C and 2C and Comparative Examples 1C and 2C (prepolymers (I) and (2), ADIPRENE L325, or DC6912) were collected in a container, and to the container, 5 ml of N,N-dimethylformamide (DMF) solution containing methanol (methanol concentration: 33% by weight) was added to obtain a mixed solution of prepolymer, methanol, and DMF. The mixed solution in the container was stirred while heated at 60° C. for 1 hour to allow methanol to react with an isocyanate group in the prepolymer to sufficiently block (deactivate) the isocyanate group. The container containing the mixed solution after the inactivation of isocyanate group was left to stand overnight at room temperature (about 25° C.) and allowed to cool down. After cooling down, 5 ml of a DMF solution with a lithium bromide concentration of 10 mM (mmol/L) was added to the mixed solution in the container, and the mixture was stirred. From the container, 0.4 mL of the mixed solution after stirring was collected, transferred to another container, and a DMF solution with a lithium bromide concentration of 5 mM was added to the container to prepare a solution such that the final concentration was about 1% by weight. The obtained solution was filtered through a 45 μm mesh filter, and the solids obtained on the filter after filtration were used as each sample.

### (Measurement Method)

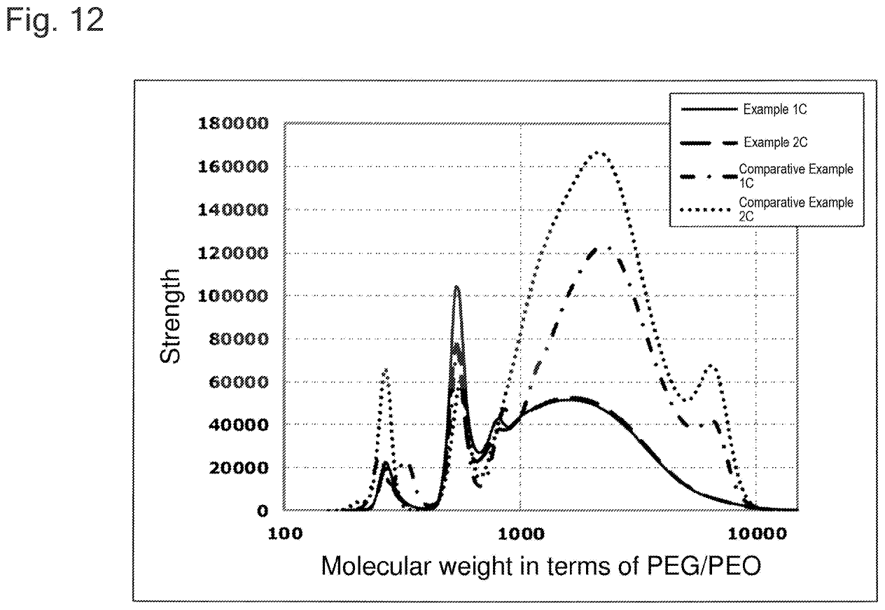

For each sample obtained as described above, the molecular weight distribution in terms of polyethylene glycol/polyethylene oxide (PEG/PEO) was measured by GPC measurement under the following measurement conditions. A peak that was present in a molecular weight range of 200 to 400, a peak that was present in a molecular weight range of 400 to 700, and a peak that was present in a molecular weight range of 700 to 10000 were designated as peak 1, peak 2, and peak 3, respectively, and the number average molecular weight and weight average molecular weight of the entire molecular weight distribution, as well as the number average molecular weight, weight average molecular weight, peak top, and abundance ratio of each of peaks 1 to 3, were measured. The measurement results are shown in Table 13 and FIG. 12.

### (Measurement Conditions)

Column: Ohpak SB-802.5 HQ (exclusion limit 10000)+SB-803 HQ (exclusion limit 100000)
Mobile phase: 5 mM LiBr/DMF
Flow rate: 0.3 ml/min (26 kg/cm²)
Oven: 60° C.
Detector R¹ 40° C.
Sample volume: 20 μl

TABLE 13

| | Molecular weight | | | | | | | | | | | | | |
|---|---|---|---|---|---|---|---|---|---|---|---|---|---|---|
| | | | Peak 1 | | | | Peak 2 | | | | Peak 3 | | | |
| | Entirety | | | | | Abundance | | | | Abundance | | | | Abundance |
| | M.N. | M.W. | M.N. | M.W. | M.P. | ratio | M.N. | M.W. | M.P. | ratio | M.N. | M.W. | M.P. | ratio |
| Example 1C | 862 | 1476 | 278 | 280 | 270 | 5.8% | 546 | 550 | 538 | 25.2% | 1425 | 1933 | 1619 | 69.0% |
| Example 2C | 918 | 1578 | 277 | 280 | 269 | 5.7% | 542 | 546 | 537 | 19.7% | 1451 | 1967 | 1625 | 74.6% |
| Comparative | 1080 | 2097 | 250 | 251 | 253 | 8.0% | 544 | 548 | 548 | 7.0% | 1805 | 2474 | 2256 | 85.0% |
| Example 1C | | | | | | | | | | | | | | |
| Comparative | 1140 | 2157 | 263 | 265 | 269 | 6.9% | 554 | 560 | 564 | 10.7% | 1664 | 2061 | 2156 | 82.4% |
| Example 2C | | | | | | | | | | | | | | |

*M.N.: Number average molecular weight,
M.W.: Weight average molecular weight,
M.P.: Peak top molecular weight
*The peak top molecular weight means the molecular weight determined from the position of peak apex.
*The abundance ratio indicates the proportion of each peak present.

In Table 13 and FIG. 12, the peak that was present in a molecular weight range of 200 to 400 (peak 1) is considered to be derived from unreacted (free) 2,4-tolylene diisocyanate, the peak that was present in a molecular weight range of 400 to 700 (peak 2) is considered to be derived from a component formed by adding two molecules of 2,4-tolylene diisocyanate to both ends of one molecule of low molecular weight polyol (diethylene glycol) in the prepolymer, and the peak that was present in a molecular weight range of 700 to 10000 (peak 3) is considered to be derived from a component formed by adding two molecules of 2,4-tolylene diisocyanate to both ends of one molecule of high molecular weight polyol (polyether polycarbonate diol or polytetramethylene ether glycol) in the prepolymer, and an ultra-high molecular weight component formed by adding three or more molecules of 2,4-tolylene diisocyanate to two or more molecules of high molecular weight polyol (polyether polycarbonate diol or polytetramethylene ether glycol) in the prepolymer.

From the results of Table 13, for the isocyanate-terminated urethane prepolymers used in Examples 1C and 2C (prepolymers (1) and (2)), it was found that the number average molecular weight of the entire molecular weight distribution of the prepolymers is not more than Mna and that the peak top molecular weight of peak 3 is not more than Mna+1000 (Mna is the number average molecular weight of polyether polycarbonate diol).

Also, when the same GPC measurement is also carried out on the isocyanate-terminated urethane prepolymer used in Example 3C (prepolymer (3)), as in Examples 1C and 2C, it is considered that the number average molecular weight of the entire molecular weight distribution of the prepolymer is not more than Mna and that the peak top molecular weight of peak 3 is not more than Mna+1000 (Mna is the number average molecular weight of polyether polycarbonate diol).

### (Evaluation Methods)

For each of the polishing pads of Examples 1C and 2C and Comparative Examples 1C and 2C, the following evaluations were carried out: (1) level difference resolving performance and (2) defects.

### (1) Level Difference Resolving Performance

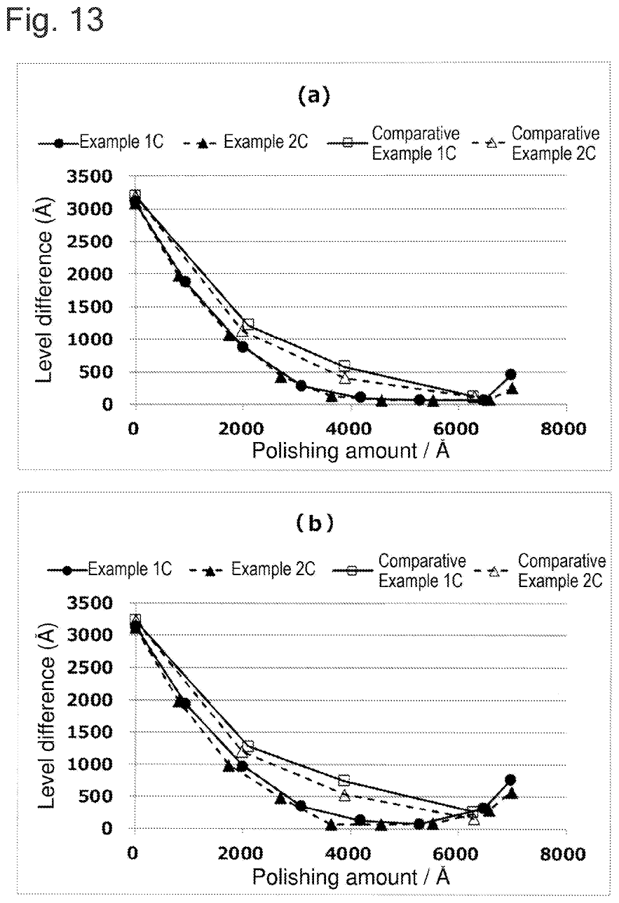

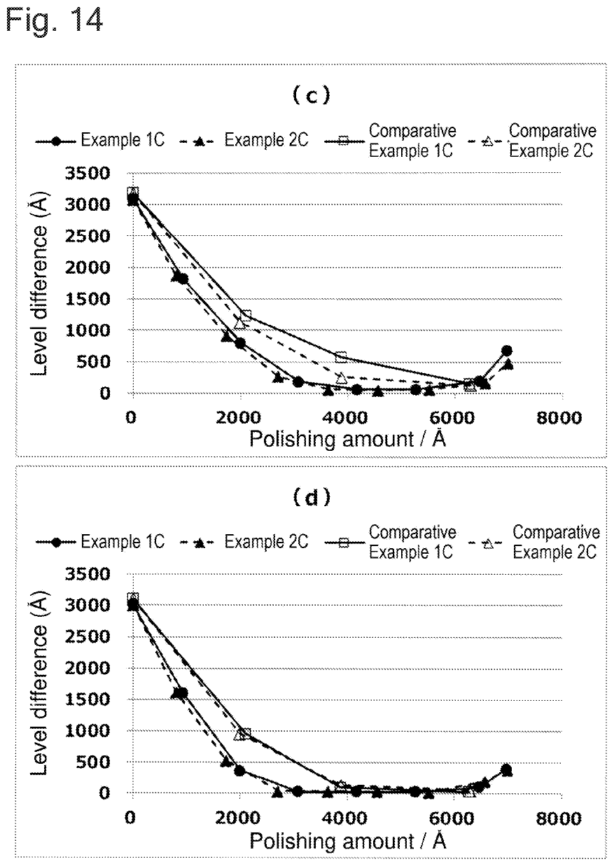

Each polishing pad was installed at a predetermined position of a polishing apparatus via double-sided tape having an acrylic adhesive, and the polishing processing was performed under the conditions shown in <Polishing conditions> below. Then, after the polishing processing, the level difference resolving performance was evaluated by measuring with a micro-shape measuring apparatus (manufactured by KLA Tencor Corporation, P-16+OF). The evaluation results for each polishing pad are shown in Table 14 and FIGS. 13 and 14.

### <Measurement Procedures and Conditions>

In the present Examples and Comparative Examples, each polishing pad was used for patterned wafers (insulating film: Si(OC₂H₅)₄ film) having a Cu film thickness of about 7000 Å and level differences of 3000 to 3300 Å and having different wiring widths, and polishing was performed adjusting the polishing rate such that the polishing amount at one time was about 1000 Å to carry out the polishing in stages, with a level difference measurement on the wafers performed at each stage. The level difference measurement was carried out on the portion of each wiring width on the patterned wafers.

The graph of FIG. 13 (a) shows the results in the case of polishing wiring with a Cu wiring width of 120 μm and an insulating film width of 120 μm, the graph of FIG. 13 (b) shows the results in the case of polishing wiring with a Cu wiring width of 100 μm and an insulating film width of 100 μm, the graph of FIG. 14 (c) shows the results in the case of polishing wiring with a Cu wiring width of 50 μm and an insulating film width of 50 μm, and the graph of FIG. 14 (d) shows the wiring with a Cu wiring width of 10 μm and an insulating film width of 10 μm. The smaller the value of wiring width, the finer the wiring.

### <Polishing Conditions>

Polishing machine used: F-REX300X (manufactured by EBARA CORPORATION)
Disk: A188 (manufactured by 3M Company)
Temperature of polishing agent: 20° C.
Rotation speed of polishing turn table: 90 rpm
Rotation speed of polishing head: 81 rpm
Polishing pressure: 3.5 psi
Polishing slurry: CSL-9044C (a mixed solution with a weight ratio of CSL-9044C undiluted solution:pure water=1:9 was used)(manufactured by FUJIFILM Planar Solutions, LLC)
Flow rate of polishing slurry: 200 ml/min
Polishing time: 60 seconds
Workpiece to be polished: (level difference resolving performance) each patterned wafer mentioned above, (defects) Cu film substrate
Pad break: 32N 10 minutes
Conditioning: in-situ 18N 16 scans, Ex-situ 35N 4 scans

### (2) Defects

Each polishing pad was installed at a predetermined position of a polishing apparatus via double-sided tape having an acrylic adhesive, and the polishing processing was performed on a Cu film substrate (12-inch diameter disk) under the conditions shown in the above-mentioned <Polishing conditions> of (1) Level difference resolving performance.

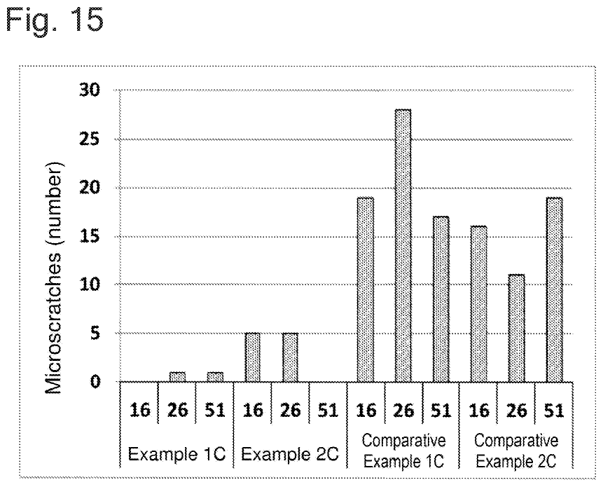

The 16th, 26th, and 51st Cu film substrates treated by polishing were measured with the high sensitivity measurement mode of a surface inspection apparatus (manufactured by KLA-Tencor Corporation, Surfscan SP2XP), and the number of microscratches (scratches in the form of fine dents of 0.2 μm or more and 10 μm or less) on the entire substrate surface was observed, the total of which was then determined. The evaluation results are shown in Table 15 and FIG. 15.

It can be said that, when the number of microscratches is 5 or less, the number of defects is small, which is good.

TABLE 14

| | | | Polishing amount (Å) | | | | | | | |
|---|---|---|---|---|---|---|---|---|---|---|
| | | | 0 | 934 | 1995 | 3085 | 4181 | 5281 | 6474 | 6975 |
| Example | Level | (a) | 3107 | 1874 | 876 | 282 | 96 | 62 | 64 | 447 |
| 1C | difference | (b) | 3139 | 1938 | 976 | 346 | 126 | 75 | 317 | 762 |
| | (Å) | (c) | 3092 | 1808 | 794 | 185 | 62 | 61 | 195 | 674 |
| | | (d) | 3019 | 1601 | 370 | 29 | 28 | 29 | 108 | 402 |

Polishing amount (Å)

| | | | 0 | 802 | 1739 | 2698 | 3632 | 4557 | 5529 | 6570 | 6992 |
|---|---|---|---|---|---|---|---|---|---|---|---|
| Example | Level | (a) | 3096 | 1971 | 1068 | 426 | 128 | 60 | 59 | 72 | 246 |
| 2C | difference | (b) | 3117 | 1989 | 990 | 482 | 71 | 72 | 81 | 289 | 573 |
| | (Å) | (c) | 3074 | 1872 | 911 | 262 | 59 | 48 | 60 | 159 | 483 |
| | | (d) | 3007 | 1620 | 531 | 34 | 27 | 29 | 26 | 199 | 383 |

Polishing amount (Å)

| | | | 0 | 2094 | 3876 | 6283 |
|---|---|---|---|---|---|---|
| Comparative | Level | (a) | 3203 | 1218 | 580 | 122 |
| Example | difference | (b) | 3234 | 1285 | 749 | 268 |
| 1C | (Å) | (c) | 3185 | 1234 | 570 | 150 |
| | | (d) | 3110 | 960 | 100 | 30 |

Polishing amount (Å)

| | | | 0 | 1980 | 3875 | 6287 |
|---|---|---|---|---|---|---|
| Comparative | Level | (a) | 3203 | 1130 | 405 | 111 |
| Example | difference | (b) | 3234 | 1198 | 531 | 156 |
| 2C | (Å) | (c) | 3185 | 1126 | 257 | 128 |
| | | (d) | 3110 | 957 | 138 | 52 |

* (a) to (d) in Table 14 indicate the following.
(a): Polishing of wiring portion with a Cu wiring width of 120 μmm and an insulating film width of 120 μm on the patterned wafer
(b): Polishing of wiring portion with a Cu wiring width of 100 μm and an insulating film width of 100 μm on the patterned wafer
(c): Polishing of wiring portion with a Cu wiring width of 50 μm and an insulating film width of 50 μm on the patterned wafer
(d): Polishing of wiring portion with a Cu wiring width of 10 μm and an insulating film width of 10 μm on the patterned wafer

TABLE 15

| | | | | | | | Comparative | | | Comparative | | |
|---|---|---|---|---|---|---|---|---|---|---|---|---|
| | Example 1C | | | Example 2C | | | Example 1C | | | Example 2C | | |
| Number of | 16 | 26 | 51 | 16 | 26 | 51 | 16 | 26 | 51 | 16 | 26 | 51 |
| substrates | | | | | | | | | | | | |
| treated by | | | | | | | | | | | | |
| polishing | | | | | | | | | | | | |
| Microscratches | 0 | 1 | 1 | 5 | 5 | 0 | 19 | 28 | 17 | 16 | 11 | 19 |
| (number) | | | | | | | | | | | | |

The polishing pads of Examples 1C and 2C relate to isocyanate-terminated urethane prepolymers that use a polyol having a carbonate group in a molecule and having a number average molecular weight of Mna and have a number average molecular weight of not more than Mna. On the other hand, the polishing pads of Comparative Examples 1C and 2C relate to isocyanate-terminated urethane prepolymers not using a polyol having a carbonate group in a molecule. As for the polishing pads of Examples 1C and 2C, the number average molecular weight of the isocyanate-terminated urethane prepolymers used is not more than Mna and they have excellent uniformity, and it is thus considered that the characteristics of the carbonate group can be expressed more prominently.

From the results of Tables 14 and 15 and FIGS. 13 to 15, it was found that the polishing pads of Examples 1C and 2C have superior level difference resolving performance in all wiring widths compared to the polishing pads of Comparative Examples 1C and 2C, and that scratches are significantly decreased and the occurrence of defects can be suppressed. This tendency is considered to be the same in Example 3C as well.

From the above, it was found that a polishing pad formed from an isocyanate-terminated urethane prepolymer that uses a polyol having a carbonate group in a molecule and having a number average molecular weight of Mna and has an average molecular weight of not more than Mna has excellent uniformity and can express the characteristics of the carbonate group more prominently, as a result of which dishing at the time of polishing can be suppressed (excellent level difference resolving performance) and the occurrence of defects can be suppressed.

1. A polishing pad having a polishing layer comprising a polyurethane resin,
wherein the polyurethane resin is a cured product of a curable resin composition comprising an isocyanate-terminated urethane prepolymer and a curing agent, and the isocyanate-terminated urethane prepolymer is a reaction product of a polyol component and a polyisocyanate component, and
the polyol component comprises a polyol having a carbonate group in a molecule.

2. The polishing pad according to claim 1, wherein the polyol having a carbonate group is a polyether polycarbonate diol represented by the following formula (I): 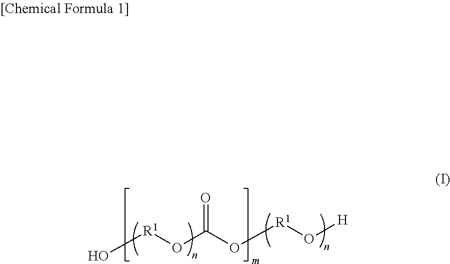
wherein
R¹ is a divalent hydrocarbon group having 2 to 10 carbon atoms, and a plurality of R¹ is identical or different;
n is an integer of 2 to 30; and
m is an integer of 1 to 20.

3. The polishing pad according to claim 2, wherein R¹ in the above formula (I) is a n-butylene group and/or a 2-methylbutylene group.

4. The polishing pad according to claim 2, wherein the polyether polycarbonate diol comprises a structural unit derived from a polytetramethylene ether glycol, and a number average molecular weight of the structural unit derived from the polytetramethylene ether glycol is 100 to 1500.

5. The polishing pad according to claim 2, wherein a number average molecular weight of the polyether polycarbonate diol is 200 to 5000.

6. The polishing pad according to claim 1,
wherein the polyol component comprises a high molecular weight polyol, and the high molecular weight polyol comprises the polyol having a carbonate group in a molecule, and
a content of the carbonate group is 1.5 to 21.0% by weight relative to the entire polyol having a carbonate group in a molecule.

7. The polishing pad according to claim 6, wherein the polyol having a carbonate group in a molecule comprises a structural unit derived from a polytetramethylene ether glycol.

8. The polishing pad according to claim 6, wherein the polyol having a carbonate group in a molecule comprises a polyether polycarbonate diol represented by the following formula (II): 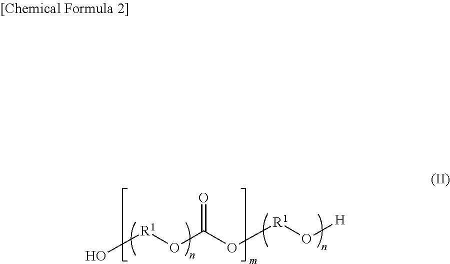
wherein
R¹ is a divalent hydrocarbon group having 2 to 10 carbon atoms, and a plurality of R¹ is identical or different;
n is 2 to 30; and
m is 0.1 to 20.

9. (canceled)

10. (canceled)

11. (canceled)

12. The polishing pad according to claim 6, wherein a content of the carbonate group in the polyol having a carbonate group in a molecule is 0.5 to 6.4% by weight relative to the entire polishing layer.

13. The polishing pad according to claim 1,
wherein the polyol component comprises a high molecular weight polyol,
the high molecular weight polyol comprises the polyol having a carbonate group in a molecule, and a number average molecular weight of the polyol having a carbonate group in a molecule is Mna, and
a number average molecular weight of the isocyanate-terminated urethane prepolymer is not more than Mna.

14. The polishing pad according to claim 13, wherein, in molecular weight distribution in terms of polyethylene glycol/polyethylene oxide (PEG/PEO) as measured by gel permeation chromatography (GPC) of the isocyanate-terminated urethane prepolymer, a peak top molecular weight of a peak that is present in a molecular weight range of 700 to 10000 is not more than Mna+1000.

15. The polishing pad according to claim 13, wherein the number average molecular weight Mna of the polyol having a carbonate group in a molecule is 500 to 2500.

16. (canceled)

17. The polishing pad according to claim 13, wherein the number average molecular weight of the isocyanate-terminated urethane prepolymer is 2000 or less.

18. The polishing pad according to claim 13, wherein the polyol having a carbonate group in a molecule comprises a structural unit derived from a polytetramethylene ether glycol.

19. The polishing pad according to claim 13, wherein the polyol having a carbonate group in a molecule comprises a polyether polycarbonate diol represented by the following formula (III): 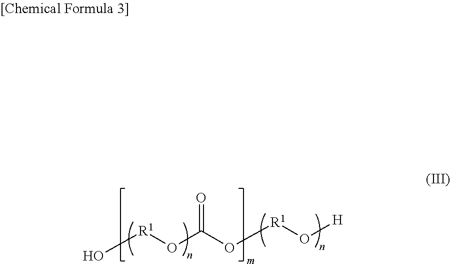
wherein
R¹ is a divalent hydrocarbon group having 2 to 10 carbon atoms, and a plurality of R¹ is identical or different;
n is 2 to 30; and
m is 0.1 to 20.

20. (canceled)

21. (canceled)

22. The polishing pad according to claim 1, wherein the polyisocyanate component comprises tolylene diisocyanate.

23. The polishing pad according to claim 1, wherein the curing agent comprises 3,3′-dichloro-4,4′-diaminodiphenylmethane.

24. The polishing pad according to claim 1, wherein the curable resin composition further comprises a micro hollow sphere.

25. A method for producing the polishing pad according to claim 1, the method comprising a step of forming the polishing layer.

26. A method for polishing a surface of an optical material or a semiconductor material, the method comprising a step of polishing a surface of an optical material or a semiconductor material using the polishing pad according to claim 1.
